(19) United States
(12) Patent Application Publication
(10) Pub. No.: US 2006/0091397 A1
(43) Pub. Date: May 4, 2006

(54) Display device and method for manufacturing the same

(76) Inventors: Kengo Akimoto, Atsugi (JP); Hotaka Maruyama, Atsugi (JP); Norihito Sone, Sagamihara (JP); Hisao Ikeda, Atsugi (JP); Junichiro Sakata, Atsugi (JP); Satoshi Seo, Kawasaki (JP)

Correspondence Address: FISH & RICHARDSON P.C., P.O. BOX 1022, MINNEAPOLIS, MN, 55440-1022, US

(21) Appl. No.: 11/253,738

(22) Filed: Oct. 20, 2005

(30) Foreign Application Priority Data
Nov. 4, 2004 (JP) 2004-320381

(51) Int. Cl. H01L 29/04

(52) U.S. Cl. 257/72

(57) ABSTRACT

It is an object of the invention to manufacture a highly reliable display device at a low cost with high yield. A display device of the invention includes: a first reflective electrode layer; and a second transparent electrode layer with an electroluminescent layer interposed therebetween, wherein the electroluminescent layer has a layer containing an organic compound and an inorganic compound, and the first electrode layer contains an aluminum alloy containing at least one or more selected from the group consisting of molybdenum, titanium, and carbon.

### BACKGROUND OF THE INVENTION

1. Field of the Invention

The invention relates to a display device and a method for manufacturing the same.

2. Description of the Related Art

As the screen of a display device having an electroluminescent (hereinafter also referred to as EL) element or a liquid crystal element is larger, and definition thereof is higher, pure aluminum attracts attention as a wiring material since pure aluminum has low resistivity and it is easily processed into a wiring.

However, pure aluminum has problem in heat resistance. A heat treatment in the manufacturing process of a display device generates a bump-like projection called a hillock on a pure aluminum film surface. Such a hillock causes a short circuit between wirings, which results in a defect.

Therefore, a wiring material which is low resistant and highly heat resistant and in which hillocks are reduced is desired to be used. An aluminum alloy thin film added with another element is accordingly developed (for example, reference 1: Japanese Patent Application Laid-Open No. 2003-89864).

### SUMMARY OF THE INVENTION

It is an object of the present invention to provide a technique by which a display device having high reliability and good electric characteristics can be formed with high yield without complexity of the process and apparatuses by using a wiring material which is low resistant and highly heat resistant, which can suppress generation of hillocks.

In the present invention, a first electrode layer that is a reflective electrode contains an aluminum alloy containing at least one or more selected from the group consisting of molybdenum, titanium, and carbon. A film containing an aluminum alloy containing at least one or more selected from the group consisting of molybdenum, titanium, and carbon is hardly crystallized by heat treatment and has good planarity on the film surface. Further, the film has high reflectance even to light in the near visible region; thus, highly efficient light reflection can be conducted. The film containing an aluminum alloy containing at least one or more selected from the group consisting of molybdenum, titanium, and carbon is not toxic and is safe for people and the environment, which are good advantages.

A display device to which the present invention can be applied includes a light emitting display device having a TFT connected to a light emitting element in which a layer containing an organic material or a mixture of an organic material and an inorganic material for exerting light emission called electroluminescence (hereinafter also referred to as EL) is provided between electrodes.

A display device of the present invention includes: an electroluminescent layer provided over a first reflective electrode layer; and a second transparent electrode layer is provided over the electroluminescent layer, wherein the electroluminescent layer has a layer containing an organic compound and an inorganic compound, which is in contact with the first electrode layer, and the first electrode layer contains an aluminum alloy containing at least one or more selected from the group consisting of molybdenum, titanium, and carbon.

A display device of the present invention includes: a light-transmitting conductive film over a first reflective electrode layer; an electroluminescent layer over the conductive film; and a second transparent electrode layer over the electroluminescent layer, wherein the electroluminescent layer has a layer containing an organic compound and an inorganic compound in contact with the conductive film, and the first electrode layer contains an aluminum alloy containing at least one or more selected from the group consisting of molybdenum, titanium, and carbon.

A display device of the present invention includes: a thin film transistor including a semiconductor layer, a gate insulating layer, a gate electrode layer, a source electrode layer, and a drain electrode layer; an insulating layer over the thin film transistor; an interlayer film provided over the insulating layer; a first reflective electrode layer over the interlayer film; and a second transparent electrode layer over the electroluminescent layer, wherein the electroluminescent layer has a layer containing an organic compound and an inorganic compound, which is in contact with the first electrode layer, the interlayer film is provided only under the first electrode layer, and the first electrode layer contains an aluminum alloy containing at least one or more selected from the group consisting of molybdenum, titanium, and carbon.

A display device of the present invention includes: a thin film transistor including a semiconductor layer, a gate insulating layer, a gate electrode layer, a source electrode layer, and a drain electrode layer; an insulating layer over the thin film transistor; an interlayer film provided over the insulating layer; a first reflective electrode layer over the interlayer film; a light-transmitting conductive film over the first electrode layer; an electroluminescent layer provided over the conductive film; and a second transparent electrode layer over the electroluminescent layer, wherein the electroluminescent layer has a layer containing an organic compound and an inorganic compound in contact with the conductive film, the interlayer film is provided only under the first electrode layer, and the first electrode layer contains an aluminum alloy containing at least one or more selected from the group consisting of molybdenum, titanium, and carbon.

A method for manufacturing a display device of the present invention includes the steps of: forming a first reflective electrode layer containing an aluminum alloy containing at least one or more selected from the group consisting of molybdenum, titanium, and carbon; forming an electroluminescent layer over the first electrode layer; and forming a second transparent electrode layer over the electroluminescent layer, wherein the electroluminescent layer is formed so that a layer containing an organic compound and an inorganic compound is in contact with the first electrode layer.

A method for manufacturing a display device of the present invention includes the steps of: A method for manufacturing a display device, comprising the steps of: forming a first reflective electrode layer containing an aluminum alloy containing at least one or more selected from the group consisting of molybdenum, titanium, and carbon; a light-transmitting conductive film is formed over the first electrode layer; forming an electroluminescent layer over the conductive film; and forming a second transparent electrode layer over the electroluminescent layer, the electroluminescent layer is formed so that a layer containing an organic compound and an inorganic compound is in contact with the conductive film.

A method for manufacturing a display device of the present invention includes the steps of: forming a thin film transistor including a semiconductor layer, a gate insulating layer, a gate electrode layer, a source electrode layer, and a drain electrode layer; forming an insulating layer over the thin film transistor; forming an interlayer film over the insulating layer; forming an opening in the insulating layer and the interlayer film, which reaches to the source electrode layer or the drain electrode layer; forming a conductive film containing at least one or more selected from the group consisting of molybdenum, titanium, and carbon over the opening and the interlayer film so as to contact the source electrode layer or the drain electrode layer; patterning the conductive film and the interlayer film to form a first reflective electrode layer; forming an electroluminescent layer over the first electrode layer; and forming a second transparent electrode layer over the electroluminescent layer, wherein the electroluminescent layer is formed so that a layer containing an organic compound and an inorganic compound is in contact with the first electrode layer.

A method for manufacturing a display device, comprising the steps of: forming a thin film transistor including a semiconductor layer, a gate insulating layer, a gate electrode layer, a source electrode layer, and a drain electrode layer; forming an insulating layer over the thin film transistor; forming an interlayer film over the insulating layer; forming an opening in the insulating layer and the interlayer film, which reaches to the source electrode layer or the drain electrode layer; forming a first conductive film containing at least one or more selected from the group consisting of molybdenum, titanium, and carbon over the opening and the interlayer film so as to contact the source electrode layer or the drain electrode layer; forming a second conductive film over the first conductive film; patterning the first conductive film, the second conductive film, and the interlayer film to form a first reflective electrode layer; forming an electroluminescent layer over the first electrode layer; and forming a second transparent electrode layer over the electroluminescent layer, wherein the electroluminescent layer is formed so that a layer containing an organic compound and an inorganic compound is in contact with the first electrode layer.

A highly reliable display device can be manufactured by applying the present invention. Accordingly, a display device with high definition and high image quality can be manufactured with high yield

### BRIEF DESCRIPTION OF THE DRAWINGS

FIGS. 1A and 1B each shows a display device of the present invention.

FIGS. 2A to 2D show a manufacturing method of a display device of the present invention.

FIGS. 3A to 3C show a manufacturing method of a display device of the present invention.

FIGS. 4A and 4B show a manufacturing method of a display device of the present invention.

FIGS. 5A to 5C show a manufacturing method of a display device of the present invention.

FIGS. 6A and 6B show a manufacturing method of a display device of the present invention.

FIGS. 7A and 7B each shows a display device of the present invention.

FIGS. 8A and 8B show a manufacturing method of a display device of the present invention.

FIG. 9 shows a display device of the present invention.

FIG. 10 shows a display device of the present invention.

FIG. 11 shows a display device of the present invention.

FIG. 12 shows a display device of the present invention.

FIGS. 13A to 13C each shows a display device of the present invention.

FIG. 14 shows a schematic view of an equivalent circuit of a display device shown in FIG. 15.

FIG. 15 shows a display device of the present invention.

FIGS. 16A to 16C each shows a top view of a display device of the present invention.

FIGS. 17A and 17B each shows a top view of a display device of the present invention.

FIGS. 18A and 18B each shows a structure of a light emitting element which can be applied to the present invention.

FIGS. 19A to 19D are electronic devices to which the present invention is applied.

FIGS. 20A and 20B are electronic devices to which the present invention is applied.

FIGS. 21A and 21B are electronic devices to which the present invention is applied.

FIG. 22 is an electronic device to which the present invention is applied.

FIGS. 23A to 23C are graphs each showing an experimental data of samples in Embodiment 1.

FIGS. 24A and 24B are graphs each showing an experimental data of samples in Embodiment 1.

FIGS. 25A and 25B are graphs each showing an experimental data of samples in Embodiment 1.

FIG. 26 shows an instillation method which can be applied to the present invention.

FIG. 27 is a block diagram showing a main structure of an electronic device to which the present invention is applied.

### DETAILED DESCRIPTION OF THE INVENTION

Embodiment Modes and Example of the present invention will be described in detail with reference to the accompanying drawings. However, the invention is not limited to the following description and it is easily understood by those skilled in the art that various changes and modifications are possible, unless such changes and modifications depart from the content and the scope of the invention. Therefore, the invention is to be interpreted without limitation to the description in Embodiment Modes and the Example shown below. Note that, in the structure of the invention described hereinafter, the same reference numerals denote the same parts or parts having the similar functions in different drawings and the explanation will not be repeated.

### EMBODIMENT MODE 1

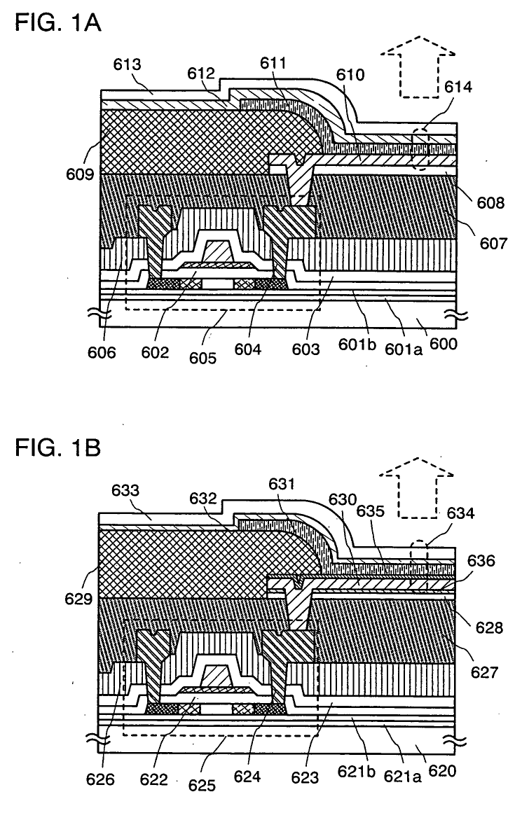

Display devices of the present embodiment mode will be described with reference to FIGS. 1A and 1B.

As shown in FIGS. 1A and 1B, a display device according to the present embodiment mode is a top-emission display device in which light is extracted through a sealing substrate. The display devices shown in FIGS. 1A and 1B are examples having light emitting elements of different structures.

The display device of FIG. 1A includes, over a substrate 600, a base film 601a, a base film 601b, a thin film transistor 605, a gate insulating layer 602, an insulating layer 603, an insulating layer 606, an insulating layer 607, an interlayer film 608, an insulating layer 609 serving as a bank, a first electrode layer 610, an electroluminescent layer 611, a second electrode layer 612, and a protective film 613. The thin film transistor 605 includes a semiconductor layer having an impurity region which serves as a source region and a drain region, a gate insulating layer 602, a gate electrode layer of a two-layer structure, a source electrode layer, and a drain electrode layer. The source electrode layer or the drain electrode layer electrically connects to the impurity region of the semiconductor layer, so as to be in contact with the first electrode layer 610.

In the display device of the present embodiment mode, the first electrode layer 610 is a reflective electrode layer, which reflects light emitted from the light emitting element 614. Therefore, light is emitted in the direction of the arrow from the second electrode layer 612. Thus, the reflective electrode layer used for a pixel electrode of a light emitting element is required to have high reflectance and good surface planarity.

In the present invention, a film containing an aluminum alloy containing at least one or more selected from the group consisting of molybdenum, titanium, and carbon is used for the first electrode layer 610 that serves as the reflective electrode layer. In the present embodiment mode, a film containing an aluminum alloy containing molybdenum (hereinafter also referred to as Al(Mo) film) is used. The film containing an aluminum alloy containing at least one or more selected from the group consisting of molybdenum, titanium, and carbon is hardly crystallized by heat treatment and has good planarity on the film surface. Further, the film has high reflectance even to light in the near visible region; thus, highly efficient light reflection can be conducted. The film containing an aluminum alloy containing at least one or more selected from the group consisting of molybdenum, titanium, and carbon is not toxic and is safe for people and the environment, which are good advantages.

Further, an aluminum alloy containing nickel has low resistance to a chemical solution such as a developing solution used in forming the insulating layer 609 serving as a bank which covers a part of the first electrode layer 610. On the other hand, a film containing an aluminum alloy containing at least one or more selected from the group consisting of molybdenum, titanium, and carbon in the present invention has high resistance. In particular, a film containing an aluminum alloy containing titanium (hereinafter also referred to as Al(Ti) film) and a film containing an aluminum alloy containing 20 atomic % or more of molybdenum have high resistance to the chemical solution; therefore, with the use of the films, a defect such as reduction in the surface or surface roughness is hardly caused in the manufacturing process. Thus, good surface condition can be kept, so that the electroluminescent layer 611 to be formed thereon can be formed stably, and the reliability of the display device can be increased accordingly. Naturally, a developing solution which is highly protective against corrosion is preferably used for the developing solution, which is effective. Further, if the content of molybdenum or titanium in the film containing an aluminum alloy containing at least one or more selected from the group consisting of molybdenum, titanium, and carbon is increased, the effect of suppressing polarization of light emitted from the light emitting element can be expected.

In the film containing an aluminum alloy containing at least one or more selected from the group consisting of molybdenum, titanium, and carbon, the content of molybdenum or titanium is preferably more than 7.0 atomic %. Further, in the case where the content of molybdenum or titanium in the film containing an aluminum alloy containing at least one or more selected from the group consisting of molybdenum, titanium, and carbon, is 20 atomic % or less, and an advantage of high reflectance to light in the visible region can be achieved. In a film containing an aluminum alloy containing carbon (hereinafter also referred to as Al(C) film), the content of carbon may be in the range of 0.1 atomic % to 10 atomic %, preferably, less than 1 atomic %. In a film containing an aluminum alloy containing molybdenum and carbon and a film containing an aluminum alloy containing titanium and carbon, effect can be obtained even when the content of carbon is minute; the content of carbon may be 0.3 atomic % or less or even 0.1 atomic % or less.

A film containing an aluminum alloy containing titanium is also referred to as a film containing a titanium-aluminum alloy, and a film containing an aluminum alloy containing carbon is also referred to as an aluminum alloy carbon film or an aluminum-carbon alloy film.

In this embodiment mode, the substrate 600 is formed with a glass substrate, the base film 601a is formed with a silicon nitride oxide film, the base film 601b is formed with a silicon oxynitride film, the gate insulating layer 602 is formed with a silicon oxynitride film, the insulating layer 603 is formed with a silicon nitride oxide film, the insulating layer 606 is formed with a silicon oxide film, the insulating layer 607 is formed with a silicon oxide film having an alkyl group, the interlayer film 608 is formed with a silicon nitride oxide film, the insulating layer 609 serving as a bank contains polyimide, and the protective film 613 is formed with a silicon nitride oxide film. The interlayer 608 is formed to improve the adhesion between the electrode layer 610 and the insulating layer 607.

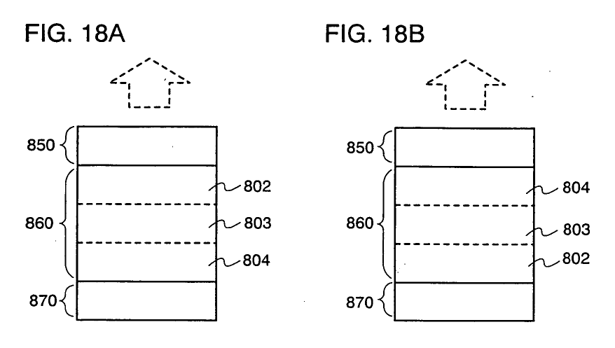

The structure of the light emitting element 614 applicable in the present embodiment mode will be described in details with reference to FIGS. 18A and 18B. In FIGS. 18A and 18B, a first electrode layer 870 corresponds to the first electrode layer 610 in FIG. 1A, an electroluminescent layer 860 corresponds to the electroluminescent layer 611, and a second electrode layer 850 corresponds to the second electrode layer 612.

FIGS. 18A and 18B each shows an element structure of a light emitting element of the present invention, in which the electroluminescent layer 860 that is a mixture of an organic compound and an inorganic compound is provided between the first electrode layer 870 and the second electrode layer 850. The electroluminescent layer 860 includes a first layer 804, a second layer 803, and a third layer 802 as shown in the figures. The first layer 804 and the third layer 802 have special features.

First, the first layer 804 is a layer that takes on the function of transporting holes to the second layer 803, and includes at least a first organic compound and a first inorganic compound that exhibits an electron accepting property to the first organic compound (serves as an electron acceptor). What is important is that the first inorganic compound is not only mixed with the first organic compound but also exhibits an electron accepting property to the first organic compound (serves as an electron acceptor). This structure generates a lot of hole carriers in the first organic compound, which originally has almost no inherent carrier, to provide an excellent hole injecting and/or hole transporting property.

Therefore, the first layer 804 provides not only advantages that are considered obtained by mixing an inorganic compound (for example, improvement in heat resistance) but also excellent conductivity (in particular, hole injecting and/or transporting properties in the case of the first layer 804). This excellent conductivity is an advantage that is not able to be obtained from a conventional hole transporting layer in which an organic compound and an inorganic compound that do not electronically interact with each other are simply mixed. This advantage makes it possible to lower a driving voltage more than ever before. In addition, since the first layer 804 can be made thicker without causing an increase in driving voltage, short circuit of the element due to dust and the like can also be suppressed.

Meanwhile, it is preferable to use a hole-transporting organic compound as the first organic compound since hole carriers are generated in the first organic compound as described above. Examples of the hole-transporting organic compound include, but are not limited to, phthalocyanine (abbreviation: H₂Pc), copper phthalocyanine (abbreviation: CuPc), vanadyl phthalocyanine (abbreviation: VOPc), 4,4′,4″-tris(N,N-diphenylamino)-triphenylamine (abbreviation: TDATA), 4,4′,4″-tris[N-(3-methylphenyl)-N-phenylamino]-triphenylamine (abbreviation: MTDATA), 1,3,5-tris[N,N-di(m-tolyl) amino]benzene (abbreviation: m-MTDAB), N,N′-diphenyl-N,N′-bis(3-methylphenyl)-1,1′-biphenyl-4,4′-diamine (abbreviation: TPD), 4,4′-bis[N-(1-naphthyl)-N-phenylamino]biphenyl (abbreviation: NPB), 4,4′-bis {N-[4-di(m-tolyl)amino]phenyl-N-phenylamino}biphenyl (abbreviation: DNTPD), and 4,4′,4″-tris(N-carbazolyl)triphenylamine (abbreviation: TCTA). In addition, of the compounds mentioned above, aromatic amine compounds as typified by TDATA, MTDATA, m-MTDAB, TPD, NPB, DNTPD, and TCATA easily generate hole carriers, and are a suitable group of compounds for the first organic compounds.

While on the other hand, the first inorganic compound may be any material as long as the material easily accepts electrons from the first organic compound, and various metal oxides and metal nitrides can be used. However, transition metal oxides each having a transition metal that belongs to any one of Groups 4 to 12 of the periodic table are preferred since an electron accepting property is easily provided. Specifically, the transition metal oxides include titanium oxide, zirconium oxide, vanadium oxide, molybdenum oxide, tungsten oxide, rhenium oxide, ruthenium oxide, and zinc oxide. In addition, of the metal oxides mentioned above, many of transition metal oxides each having a transition metal that belongs to any one of Groups 4 to 8 have a higher electron accepting property, which are a preferable group of compounds. In particular, vanadium oxide, molybdenum oxide, tungsten oxide, and rhenium oxide are preferred since these oxides can be used easily for vacuum deposition.

It is to be noted that the first layer 804 may be formed by stacking a plurality of layers each including a combination of an organic compound and an inorganic compound as described above, or may further include another organic or inorganic compound.

Next, the third layer 802 will be described. The third layer 802 is a layer that takes on the function of transporting electrons to the second layer 803, includes at least a third organic compound and a third inorganic compound that exhibits an electron donating property to the third organic compound (serves as an electron donor). What is important is that the third inorganic compound is not only mixed with the third organic compound but also exhibits an electron donating property to the third organic compound (serves as an electron donor). This structure generates a lot of hole carriers in the third organic compound, which originally has almost no inherent carrier, to provide an excellent electron injecting and/or electron transporting property.

Therefore, the third layer 802 provides not only advantages that are considered obtained by mixing an inorganic compound (for example, improvement in heat resistance) but also excellent conductivity (in particular, electron injecting and/or transporting properties in the case of the third layer 802). This excellent conductivity is an advantage that is not able to be obtained from a conventional electron transporting layer in which an organic compound and an inorganic compound that do not electronically interact with each other are simply mixed. This advantage makes it possible to lower a driving voltage more than ever before. In addition, since the third layer 802 can be made thicker without causing an increase in driving voltage, short circuit of an element due to dust and the like can also be suppressed.

Meanwhile, it is preferable to use an electron-transporting organic compound as the third organic compound since electron carriers are generated in the third organic compound as described above. Examples of the hole-transporting organic compound include, but are not limited to, tris(8-quinolinolato)aluminum (abbreviation: Alq₃), tris(4-methyl-8-quinolinolato) aluminum (abbreviation: Almq₃), bis(10-hydroxybenzo[h]quinolinato) beryllium (abbreviation: BeBq₂), bis(2-methyl-8-quinolinolato) (4-phenylphenolato)-aluminum (abbreviation: BAlq), bis[2-(2′-hydroxyphenyl)benzoxazolato]zinc (abbreviation: ZnBOX) or bis[2-(2′-hydroxyphenyl) benzothiazolato]zinc (abbreviation: Zn(BTZ)₂), bathophenanthroline (abbreviation: BPhen), bathocuproin (abbreviation: BCP), 2-(4-biphenylyl)-5-(4-tert-butylphenyl)-1,3,4-oxadiazole (abbreviation: PBD), 1,3-bis[5-(4-tert-butylphenyl)-1,3,4-oxadiazole-2-yl]benzene (abbreviation: OXD-7), 2,2′,2″-(1,3,5-benzenetriyl)-tris (1-phenyl-1H-benzimidazole) (abbreviation: TPBI), 3-(4-biphenylyl)-4-phenyl-5-(4-tert-butylphenyl)-1,2,4-triazole (abbreviation: TAZ), and 3-(4-biphenylyl)-4-(4-ethylphenyl)-5-(4-tert-butylphenyl)-1,2,4-triazole (abbreviation: p-EtTAZ). In addition, of the compound mentioned above, chelate metal complexes each having a chelate ligand including an aromatic ring as typified by Alq₃, Almq₃, BeBq₂, BAlq, Zn(BOX)₂, and Zn(BTZ)₂, organic compounds each having a phenanthroline skeleton as typified by BPhen and BCP, and organic compounds each having an oxadiazole skeleton as typified by PBD and OXD-7 easily generate electron carriers, and are suitable groups of compounds for the third organic compounds.

While on the other hand, the third inorganic compound may be any material as long as the material easily donates electrons from the third organic compound, and various metal oxides and metal nitrides can be used. However, alkali metal oxides, alkaline-earth metal oxides, rare-earth metal oxides, alkali metal nitrides, alkaline-earth metal nitrides, and rare-earth metal nitrides are preferred since an electron donating property is easily provided. Specifically, examples of the oxides mentioned above include lithium oxide, strontium oxide, barium oxide, erbium oxide, lithium nitride, magnesium nitride, calcium nitride, yttrium nitride, and lanthanum nitride. In particular, lithium oxide, barium oxide, lithium nitride, magnesium nitride, and calcium nitride are preferred since these oxides and nitrides can be used easily for vacuum deposition.

It is to be noted that the third layer 802 may be formed by stacking a plurality of layers each including a combination of an organic compound and an inorganic compound as described above, or may further include another organic compound or inorganic compound.

Next, the second layer 803 will be described. The second layer 803 is a layer that takes on the function of emitting light, and includes a second organic compound that is luminescent. A second inorganic compound may be included in addition. The second layer 803 can be formed using some of various luminescent organic compounds and inorganic compounds. However, since it is believed that it is hard to apply a current to the second layer 803 as compared with the first layer 804 or the third layer 802, it is preferable that the thickness of the second layer 803 be approximately 10 to 100 nm.

The second organic compound is not particularly limited as ling as a luminescent organic compound is used, and examples of the second organic compound include 9,10-di(2-naphthyl)anthracene (abbreviation: DNA), 9,10-di (2-naphthyl)-2-tert-butylanthracene (abbreviation: t-BuDNA), 4,4′-bis (2,2-diphenylvinyl)biphenyl (abbreviation: DPVBi), coumarin 30, coumarin 6, coumarin 545, coumarin 545T, perylene, rubrene, periflanthene, 2,5,8,11-tetra (tert-butyl)perylene (abbreviation: TBP), 9,10-diphenylanthracene (abbreviation: DPA), 4-(dicyanomethylene)-2-methyl-[p-(dimethylamino) styryl]-4H-pyran (abbreviation: DCM1), 4-(dicyanomethylene)-2-methyl-6-[2-(julolidine-9-yl)ethenyl]-4H-pyran (abbreviation: DCM2), and 4-(dicyanomethylene)-2,6-bis[p-(dimethylamino)styryl]-4H-pyran (abbreviation: BisDCM). In addition, it is also possible to used compounds that are capable of producing phosphorescence such as bis [2-(4′,6′-difluorophenyl) pyridinato-N,C^{2′}]iridium (picolinate) (abbreviation: FIrpic), bis {2-[3′,5′-bis(trifluoromethyl)phenyl]pyridinato-N,C^{2′}}iridium (picolinate) (abbreviation: Ir(CF₃ppy)₂(pic)), tris(2-phenylpyridinato-N,C^{2′})iridium (abbreviation: Ir(ppy)₃), bis(2-phenylpyridinato-N,C^{2′})iridium (acetylacetonate) (abbreviation: Ir(ppy)₂(acac)), bis[2-(2′-thienyl)pyridinato-N,C^{3′}]iridium (acetylacetonate) (abbreviation: Ir(thp)₂(acac)), bis(2-phenylquinolinato-N,C^{2′})iridium(acetylacetonate) (abbreviation: Ir(pq)₂(acac)), and bis[2-(2′- benzothienyl)pyridinato-N,C^{3′}]iridium (acetylacetonate) (abbreviation: Ir(btp)₂(acac)).

Further, a triplet light emitting material containing a metal complex or the like as well as a singlet light emitting material may be used for the second layer 803. For example, among pixels emitting red, green, and blue light, a pixel emitting red light whose luminance is reduced by half in a relatively short time is formed of a triplet light emitting material and the rest are formed of a singlet light emitting material. A triplet light emitting material has a feature of good luminous efficiency and less power consumption to obtain the same luminance. When a triplet light emitting material is used for a red pixel, only small amount of current needs to be supplied to a light emitting element. Thus, reliability can be improved. A pixel emitting red light and a pixel emitting green light may be formed of a triplet light emitting material and a pixel emitting blue light may be formed of a singlet light emitting material to achieve low power consumption. Low power consumption can be further achieved by forming a light emitting element which emits green light that has high visibility with a triplet light emitting material.

Further, the second layer 803 may include not only the second organic compound described above, which produces luminescence, but also another organic compound added. Examples of organic compounds that can be added include, but are not limited to, TDATA, MTDATA, m-MTDAB, TPD, NPB, DNTPD, TCTA, Alq₃, Almq₃, BeBq₂, BAlq, Zn(BOX)₂, Zn(BTZ)₂, BPhen, BCP, PBD, OXD-7, TPBI, TAZ, p-EtTAZ, DNA, t-BuDNA, and DPVBi, which are mentioned above, and further, 4,4′-bis(N-carbazolyl)-biphenyl (abbreviation: CBP) and 1,3,5-tris[4-(N-carbazolyl)-phenyl]benzene (abbreviation: TCPB). It is to be noted that it is preferable that the organic compound, which is added in addition to the second organic compound as described above, have larger excitation energy than the second organic compound and be added more than the second organic compound in order to make the second organic compound produce luminescence efficiently (which makes it possible to prevent concentration quenching of the second organic compound). In addition, as another function, the added organic compound may produce luminescence along with the second organic compound.

The second layer 803 may have a structure to perform color display by providing each pixel with light emitting layers having different emission wavelength ranges. Typically, a light emitting layer corresponding to each color of R (red), G (green), or B (blue) is formed. On this occasion, color purity can be improved and a pixel portion can be prevented from having a mirror surface (reflection) by providing the light emission side of the pixel with a filter which transmits light of an emission wavelength range. By providing a filter, a circularly polarizing plate or the like that is conventionally required can be omitted, and further, the loss of light emitted from the light emitting layer can be eliminated. Further, change in hue, which occurs when a pixel portion (display screen) is obliquely seen, can be reduced.

A high molecular weight light emitting material or a low molecular weight light emitting material can be used for the material of the second layer 803. A high molecular weight organic light emitting material is physically stronger than a low molecular weight material and is superior in durability of the element. In addition, a high molecular weight organic light emitting material can be formed by coating; therefore, the element can be relatively manufactured easily.

The emission color is determined depending on a material forming the light emitting layer; therefore, a light emitting element which displays desired luminescence can be formed by selecting an appropriate material for the light emitting layer. As a high molecular weight electroluminescent material which can be used for forming a light emitting layer, a polyparaphenylene-vinylene-based material, a polyparaphenylene-based material, a polythiophene-based material, or a polyfluorene-based material can be used.

As the polyparaphenylene vinylene-based material, a derivative of poly(paraphenylenevinylene) [PPV], for example, poly(2,5-dialkoxy1,4-phenylenevinylene) [RO-PPV]; poly(2-(2′-ethyl-hexoxy)-5-methoxy-1,4-phenylenevinylene) [MEH-PPV]; poly(2-(dialkoxyphenyl)-1,4-phenylenevinylene) [ROPh-PPV]; and the like can be used. As the polyparaphenylene-based material, a derivative of polyparaphenylene [PPP], for example, poly(2,5-dialkoxy-1,4-phenylene) [RO-PPP]; poly(2,5-dihexoxy-1,4-phenylene); and the like can be used. As the polythiophene-based msterial, a derivative of a derivative of polythiophene [PT], for example, poly(3-alkylthiophene) [PAT]; poly(3-hexylthiophen) [PHT]; poly(3-cyclohexylthiophen) [PCHT]; poly(3-cyclohexyl-4-methylthiophene) [PCHMT]; poly(3,4-dicyclohexylthiophene) [PDCHT]; poly[3-(4-octylphenyl)-thiophene] [POPT]; poly[3-(4-octylphenyl)-2,2bithiophene] [PTOPT]; and the like can be used. As the polyfluorene-based material, a derivative of polyfluorene [PF], for example, poly(9,9-dialkylfluorene) [PDAF]; poly(9,9-dioctylfluorene) [PDOF]; and the like can be used.

The second inorganic compound may be any inorganic material as long as luminescence of the second organic compound is not easily subject to quenching by the inorganic compound, and various, metal oxides, metal nitrides can be used. In particular, metal oxides each having a metal that belongs to Group 13 or 14 of the periodic table are preferred since luminescence of the second organic compound is not easily subject to quenching, and specifically, aluminum oxide, gallium oxide, silicon oxide, and germanium oxide are preferred. However, the second inorganic compound is node limited thereto.

It is to be noted that the second layer 803 may be formed by stacking a plurality of layers each including a combination of an organic compound and an inorganic compound as described above, or may further include another organic or inorganic compound.

A light emitting element formed with the above described materials emits light by being forward biased. A pixel of a display device formed with a light emitting element can be driven by a simple matrix mode or an active matrix mode. In any event, each pixel emits light by applying a forward bias thereto at a specific timing; however, the pixel is in a non-light-emitting state for a certain period. Reliability of a light emitting element can be improved by applying a reverse bias in the non-light-emitting time. In a light emitting element, there is a deterioration mode in which emission intensity is decreased under specific driving conditions or a deterioration mode in which a non-light-emitting region is enlarged in the pixel and. luminance is apparently decreased. However, progression of deterioration can be slowed down by alternating current driving where bias is applied forward and reversely. Thus, reliability of a light emitting device can be improved. Additionally, either of digital driving and analog driving can be applied.

A color filter (coloring layer) may be formed over the sealing substrate. The color filter (coloring layer) can be formed by a deposition method or a droplet discharge method. with the use of the color filter (coloring layer), high-definition display can also be performed. This is because a broad peak can be modified to be sharp in light emission spectrum of each RGB.

Full color display can be performed by forming a material displaying a single color and combining a color filter and a color conversion layer. The color filter (coloring layer) or the color conversion layer is formed over, for example, a second substrate (a sealing substrate) and may be attached to a substrate.

Naturally, display may be performed in monochrome. For example, an area color type display device may be manufactured by using single color emission. The area color type is suitable for a passive matrix type display area, and characters and symbols can be mainly displayed.

The materials of the first electrode layer 870 and the second electrode layer 850 are required to be selected considering the work functions. The first electrode layer 870 and the second electrode layer 850 can be either an anode or a cathode depending on the pixel structure. In this embodiment mode, in the case where a driving transistor has p-type conductivity, the first electrode layer 870 may preferably serve as an anode and the second electrode layer 850 may serve as a cathode as shown in FIG. 18A. Since the driving TFT has n-type conductivity, the first electrode layer 870 may preferably be used as a cathode and the second electrode layer 850 may be used as an anode as shown in FIG. 18B. Materials that can be used for the first electrode layer 870 or the second electrode layer 850 will be described. It is preferable to use a material that has a larger work function (specifically, a material that has a work function of 4.5 eV or more) for one of the first electrode layer 870 and the second electrode layer 850 which serves as an anode, and a material that has a smaller work function (specifically, a material that has a work function of 3.5 eV or more) for the other which serves as a cathode. However, since the first layer 804 and the third layer 802 are respectively superior in hole injecting and/or transporting property, and electron injecting and/or transporting property, either the first electrode layer 870 or the second electrode layer 850 is scarcely restricted on work function, and various materials can be used for the first electrode layer 870 and the second electrode layer 850.

The second electrode layer 850 has a light-transmitting property. In that case, a transparent conductive film may be used specifically; indium tin oxide (ITO), indium zinc oxide (IZO), indium tin oxide doped with silicon oxide (ITSO), or the like can be used. Further, even in the case of using a metal film, light can be emitted from the second electrode layer 850 by making the metal film thin (preferably, about 5 nm to 30 nm) to transmit light. A conductive film containing titanium, tungsten, nickel, gold, platinum, silver, aluminum, magnesium, calcium, or lithium, a conductive film including an alloy of the metals, and the like can be used for the second electrode layer 850. Further, the first electrode layer 870 and the second electrode layer 850 may be formed of a stack of a film containing an aluminum alloy containing at least one or more selected from the group consisting of molybdenum, titanium, and carbon and the transparent conductive film described above. In the case where a transparent conductive film of ITSO or ITSO is used for the second electrode layer 850, it may be formed over a BzOs—Li film in which Li is added to benzoxazole derivatives (BzOs) or the like can be used.

It is to be noted that the light-emitting element according to the present invention has different variations by changing the types of the first electrode layer 870 and the second electrode layer 850.

FIG. 18B shows a case where the third layer 802, the second layer, and the first layer 804 are provided in the order from the first electrode layer 870 side in the electroluminescent layer 860.

As described above, the layer sandwiched between the first electrode layer 870 and the second electrode is composed of the electroluminescent layer 860, in which an organic compound and an inorganic compound are combined, in the light-emitting element according to the present invention. The light-emitting element is a novel organic-inorganic composite light-emitting element provided with layers (that is, the first layer 804 and the third layer 802) that provide a function called a high carrier injecting and/or carrier transporting property by mixing an organic compound and an inorganic compound, which is not obtainable from only either one of the organic compound and the inorganic compound. Further, the first layer 804 and the third layer 802 are particularly required to be layers in which an organic compound and an inorganic compound are combined when provided on the first electrode layer 870 side, which serves as a reflective electrode, and may contain organic compounds only or inorganic compounds when provided on the second electrode layer 850 side.

Further, various known methods can be used as a method for forming the electroluminescent layer 860, which is a layer in which an organic compound and an inorganic compound are mixed. For example, the known methods include a co-evaporation method of evaporating both an organic compound and an inorganic compound by resistance heating. In addition, for co-evaporation, an inorganic compound may be evaporated by an electron beam (EB) while evaporating an organic compound by resistance heating. Further, the known methods also include a method of sputtering an inorganic compound while evaporating an organic compound by resistance heating to deposit the both at the same time. In addition, deposition may be performed by a wet process.

In addition, for the first electrode layer 870 and the second electrode layer 850, evaporation by resistance heating, EB evaporation, sputtering, a wet process, and the like can be used in the same way.

A display device in FIG. 1B includes a base film 621a, a base film 621b, a thin film transistor 625, a gate insulating layer 622, an insulating layer 623, an insulating layer 626, an insulating layer 627, an interlayer film 628, an interlayer film 636, an insulating layer 629 which serves as a bank, a first electrode layer 630, a transparent conductive film 635, an electroluminescent layer 631, a second electrode layer 632, a protective film 633 over a substrate 620. The thin film transistor 625 includes a semiconductor layer having an impurity region serving as a source region and a drain region; a gate insulating layer 622, a gate electrode layer having a two-layer structure; a source electrode layer; and a drain electrode layer. The source electrode layer or the drain electrode layer is connected to the impurity region of the semiconductor layer so as to contact the first electrode layer 630.

A light emitting element 634 in the display device in FIG. 1B, the first electrode layer 630, the transparent conductive film 635, the electroluminescent layer 631, and the second electrode layer 632. The first electrode layer 630 and the transparent conductive film 635 form a layered structure. A film containing an aluminum alloy containing at least one or more selected from the group consisting of molybdenum, titanium, and carbon is used for the first electrode layer 630. An ITSO film is used for the transparent conductive film 635. In the case where the transparent conductive film 635 has a layered structure as shown in FIG. 1B, the first electrode layer 630 can be protected, so that the yield can be improved. Further, a silver thin film which is made thin to transmit light is used for the second electrode layer 632.

Other components in FIG. 1B may be manufactured using the same material in the same manner as in FIG. 1A. In a display device of FIG. 1B, the interlayer film 628 is a silicon nitride oxide film, and the interlayer film 636 is a titanium nitride film. The interlayer 628 and the interlayer 636 are formed between the insulating layer 627 and the first electrode layer 630; thus, the adhesion between the insulating layer 627 and the first electrode layer 630 can be improved. Further, the titanium nitride film can contributes to static protection. A silicon oxide film containing an alkyl group, which is also used in the insulating layer 627 may be provided with a thinner thickness between the silicon nitride oxide film and the titanium nitride film used for the interlayer films.

Thus, by applying the invention, a display device with high reliability can be manufactured through simplified steps. Therefore, a display device with high definition and image quality can be manufactured at low cost with high yield.

### EMBODIMENT MODE 2

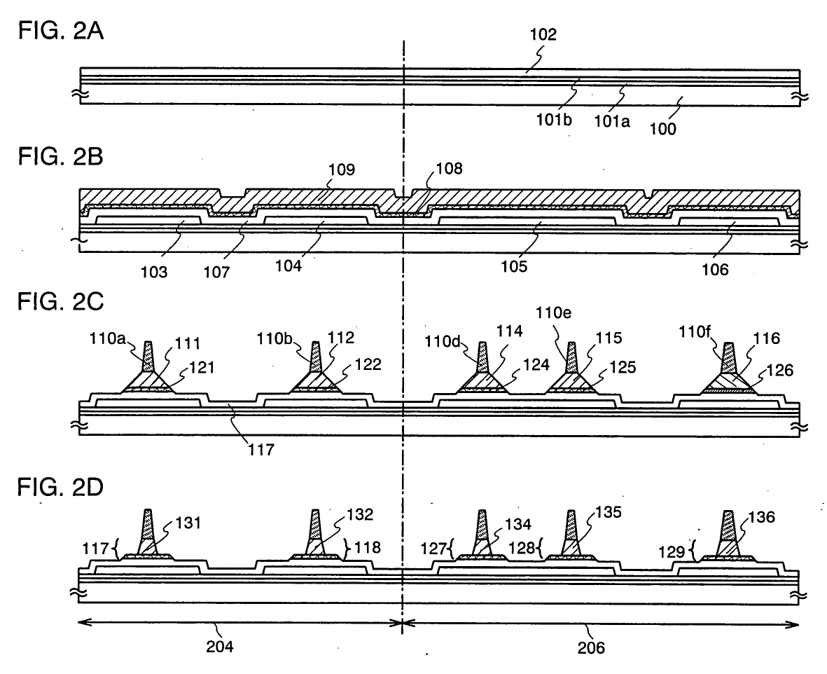

A manufacturing method of a display device according to this embodiment mode will be described in details with reference to FIGS. 2A to 7B, 16A to 16C, and 17A and 17B.

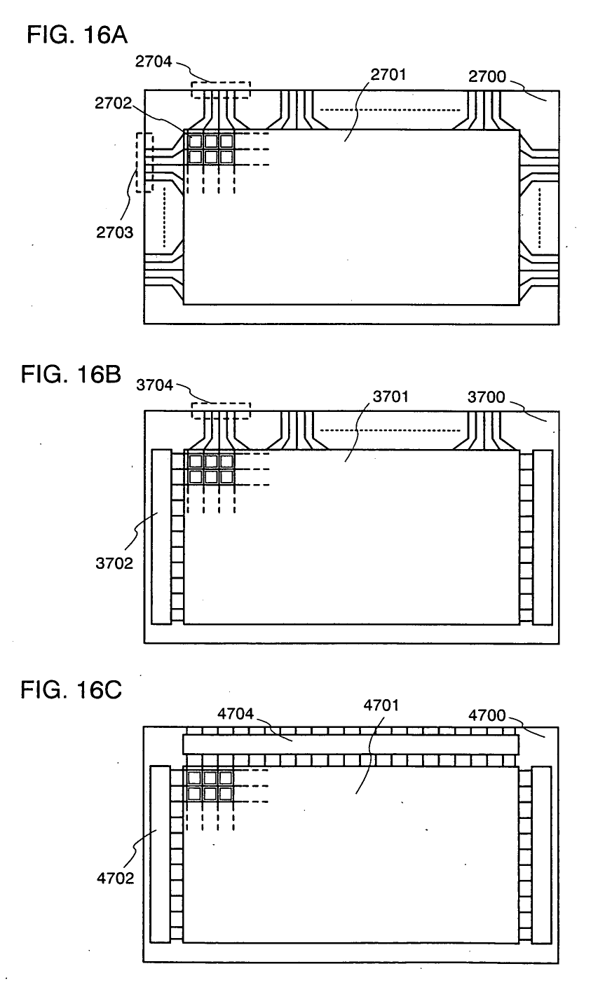

FIG. 16A is a top view showing a structure of a display panel according to the invention, including a pixel portion 2701 in which a pixel 2702 is arranged in matrix, a scan line side input terminal 2703, a signal line side input terminal 2704 which are formed over a substrate 2700 having an insulating surface. The number of pixels may be set according to various standards, for example, 1024×768×3 (RGB) in the case of XGA, 1600×1200×3 (RGB) in the case of UXGA, and 1920×1080×3 (RGB) in the case of the use for a full spec high vision display.

The pixel 2702 is arranged in matrix with a scan line extending from the scan line side input terminal 2703 and a signal line extending from the signal line side input terminal 2704 crossing. Each pixel 2702 is provided with a switching element and a pixel electrode layer connected thereto. A typical example of the switching element is a TFT. A gate electrode layer side of a TFT is connected to the scan line, and a source or drain side thereof is connected to the signal line, thereby each pixel can be controlled independently by a signal inputted from the outside.

A TFT has a semiconductor layer, a gate insulating layer and a gate electrode layer as major components. A wiring layer connected to source and drain regions formed in the semiconductor layer is further provided. Typically known are a top gate structure in which a semiconductor layer, a gate insulating layer, and a gate electrode layer are provided from a substrate side, a bottom gate structure in which a gate electrode layer, a gate insulating layer, and a semiconductor layer are provided from a substrate side and the like, and the invention may employ any of the above structures.

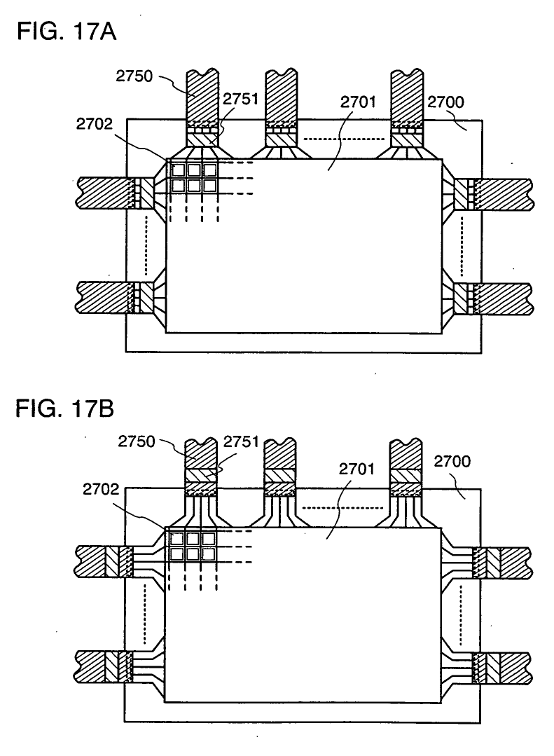

FIG. 16A shows a structure of a display panel in which a signal to be inputted to the scan line and the signal line is controlled by an external driver circuit, however, a driver IC 2751 may be mounted on the substrate 2700 by a COG (Chip On Glass) method as shown in FIG. 17A. Further, as another mode, a TAB (Tape Automated Bonding) method as shown in FIG. 17B may be employed as well. A driver IC may be formed over a single crystalline semiconductor substrate or a glass substrate over which the circuit is formed by TFTs. In FIGS. 17A and 17B, the driver IC 2751 is connected to an FPC (Flexible Printed Circuit) 2750.

Further, in the case of forming a TFT provided in a pixel using a crystalline semiconductor, a scan line side driver circuit 3702 may be integrated over a substrate 3700 as shown in FIG. 16B. In FIG. 16B, a pixel portion 3701 is controlled by an external driver circuit similarly to FIG. 16A in which the pixel portion 3701 is connected to a signal line side input terminal 3704. In the case of forming a TFT provided in a pixel using a polycrystalline (microcrystalline) semiconductor, a single crystalline semiconductor and the like with high mobility, a pixel portion 4701, a scan line driver circuit 4702, and a signal line driver circuit 4704 can be integrated over a substrate 4700.

As a base film over a substrate 100 having an insulating surface, a silicon nitride oxide film (SiNO) is formed as a base film 101a with a thickness of 10 to 200 nm (preferably 50 to 100 nm) by a sputtering method, a PVD method (Physical Vapor Deposition), and a CVD method (Chemical Vapor Deposition) such as a low pressure CVD method (LPCVD method), or a plasma CVD method and a silicon oxynitride film (SiON) is formed as a base film 101b with a thickness of 50 to 200 nm (preferably 100 to 150 nm). In this embodiment mode, the base film 101a and the base film 101b are formed by a plasma CVD method. The substrate 100 may be a glass substrate, a quartz substrate, a silicon substrate, a metal substrate, or a stainless substrate having a surface covered with an insulating film. Further, a plastic substrate which can resist a processing temperature of this embodiment mode or a flexible substrate such as a film may be used as well. As a plastic substrate, a substrate formed of PET (polyethylene terephthalate), PEN (polyethylene naphthalate), or PES (polyether sulfone) may be used while a synthetic resin such as acrylic may be used as a flexible substrate.

As a base film, silicon oxide, silicon nitride, silicon oxynitride, silicon nitride oxide and the like may be used in a single layer or stacked layers of two or three layers. It is to be noted that silicon oxynitride has a content of oxygen higher than that of nitrogen and can also be referred to as silicon oxide containing nitrogen. Similarly, silicon nitride oxide has a content of nitrogen higher than that of oxygen and can also be referred to as silicon nitride containing oxygen. In this embodiment mode, a silicon nitride oxide film is formed with a thickness of 50 nm using as a reaction gas SiH₄, NH₃, N₂O, N₂, and H₂, and a silicon oxynitride film is formed with a thickness of 100 nm using as a reaction gas SiH₄ and N₂O. Further, a silicon nitride oxide film may be formed with a thickness of 140 nm and a silicon oxynitride film to be stacked may be formed with a thickness of 100 nm.

Subsequently, a semiconductor film is formed over the base film. The semiconductor film may be formed by a known means (a sputtering method, an LPCVD method, a plasma CVD method or the like) with a thickness of 25 to 200 nm (preferably 30 to 150 nm). In this embodiment mode, it is preferable to use a crystalline semiconductor film formed by crystallizing an amorphous semiconductor film by laser irradiation.

A material for forming a semiconductor film may be an amorphous semiconductor (hereinafter also referred to as “amorphous semiconductor: AS”) formed by a vapor deposition method and a sputtering method using a semiconductor material gas typified by silane and germane, a polycrystalline semiconductor formed by crystallizing the amorphous semiconductor using an light energy and a heat energy, or a semi-amorphous semiconductor (also referred to as microcrystal and hereinafter referred to as “SAS”) and the like.

An SAS is a semiconductor having an intermediate structure between amorphous and crystalline (including single crystalline and polycrystalline) structures and having a third state which is stable in free energy. Moreover, an SAS is a crystalline semiconductor having a short distance order and lattice distortion, and formed by dispersing a grain having a diameter of 0.5 to 20 nm is dispersed at least in a portion of a film. In the case of containing silicon as a main component, Raman spectrum of an SAS is shifted toward lower wave numbers than 520 cm⁻¹. The diffraction peaks of (111) and (220), which are believed to be derived from Si crystal lattice, are observed in the SAS film by X-ray diffraction. The semi-amorphous semiconductor film contains hydrogen or halogen by at least 1 atom % or more for terminating dangling bonds. An SAS is formed by depositing a silicide gas source by glow discharge (plasma CVD). The silicide gas is typically SiH₄, as well as Si₂H₆, SiH₂Cl₂, SiHCl₃, SiCl₄, SiF₄ and the like. Also, F₂ and GeF₄ may be mixed as well. The silicide gas source may be diluted with H₂ or a mixed gas of H₂ and one or a plurality of rare gas elements such as He, Ar, Kr, and Ne. The silicide gas source is preferably diluted with the dilution ratio of 2 to 1000 times, at a pressure of approximately 0.1 to 133 Pa, and at a power supply frequency of 1 to 120 MHz, more preferably with a high frequency power of 13 to 60 MHz. It is preferable that a temperature for heating the substrate is 300° C. or less, preferably 100 to 250° C. It is preferable that impurities of atmospheric components such as oxygen, nitrogen, and carbon as impurity elements in the film be 1×10²⁰ cm⁻³ or less. In particular, oxygen concentration is preferably 5×10¹⁹/cm⁻³ or less and more preferably 1×10¹⁹/cm⁻³ or less. Further, when a rare gas element such as helium, argon, krypton, or neon is mixed into an SAS, the lattice distortion is increased and the stability is thus enhanced, leading to form a favorable SAS. Further, as the semiconductor film, an SAS layer formed by a hydrogen-based gas may be stacked over an SAS layer formed by a fluorine-based gas.

As a typical amorphous semiconductor, hydrogenated amorphous silicon may be used while polysilicon and the like may be used as a crystalline semiconductor. Polysilicon (polycrystalline silicon) includes what is called high temperature polysilicon formed using polysilicon as a main material which is formed at a processing temperature of 800° C. or higher, what is called low temperature polysilicon formed using polysilicon as a main material which is formed at a processing temperature of 600° C. or lower, polysilicon crystallized by adding an element which promotes crystallization and the like. It is needless to say that a semiconductor containing a crystal phase in a portion of a semi-amorphous semiconductor or a semiconductor film may be used as described above.

In the case of using a crystalline semiconductor film for the semiconductor film, the crystalline semiconductor film may be formed by a known method (a laser crystallization method, a thermal crystallization method, a thermal crystallization method using an element such as nickel which promotes crystallization and the like). Further, a microcrystalline semiconductor as an SAS may be crystallized by laser irradiation to enhance crystallinity. In the case where an element which promotes crystallization is not used, the amorphous semiconductor film is heated for one hour in a nitrogen atmosphere at 500° C. to let out hydrogen so that a hydrogen concentration becomes 1×10²⁰ atoms/cm³ or lower before irradiating the amorphous semiconductor film with laser light. If the amorphous semiconductor film contains a lot of hydrogen, the amorphous semiconductor film may be broken by laser light irradiation. Thermal treatment for crystallization may be performed using an annealing furnace, laser irradiation, irradiation of light emitted from a lamp (also referred to as a lamp annealing) or the like. As a thermal method, an RTA method such as a GRTA (Gas Rapid Thermal Anneal) method using a heated gas and an LRTA (Lamp Rapid Thermal Anneal) method using a lamp may be used.

A method for introducing a metal element to the amorphous semiconductor film is not limited as long as it is a method for forming the metal element over a surface or inside the amorphous semiconductor film. For example, a sputtering method, a CVD method, plasma treatment (including a plasma CVD method), an absorption method, or a method of applying a solution of metal salt can be used. Among these, a method of using a solution is easy and advantageous in that the concentration of the metal element can be easily controlled. It is desirable to form an oxide film by UV light irradiation in an oxygen atmosphere, a thermal oxidation method, treatment by using ozone water containing hydroxyl radical or using hydrogen peroxide, or the like to improve wettability of a surface of the amorphous semiconductor film to diffuse an aqueous solution over the entire surface of the amorphous semiconductor film.

In order to obtain large grain crystals in crystallization, a second to fourth harmonic of the fundamental wave of a solid state laser capable of continuous oscillation is preferably used. Typically, a second (532 nm) and third (355 nm) harmonic of an Nd: YVO₄ laser (fundamental wave is 1064 nm) is used. In specific, laser light emitted from the continuous oscillation type YVO₄ laser is converted into a harmonic by using a non-linear optical element, thereby obtaining laser light of output several W or higher. It is preferable to form laser light into a rectangular or elliptical shape on an irradiated surface by an optical system for the irradiation on an object. An energy density at this time is required to be about 0.001 to 100 MW/cm² (preferably, 0.1 to 10 MW/cm²). The semiconductor film is irradiated with the laser light at a scan rate of about 0.5 to 2,000 cm/sec (preferably 10 to 200 cm/sec).

It is preferable that a shape of a laser beam be linear. As a result, throughput can be improved. Further, it is preferable that a semiconductor film be irradiated with laser at an incident angle θ (0<θ<90°), thereby an interference of the laser can be prevented.

By scanning such laser and a semiconductor film relatively, laser irradiation can be realized. Further, a marker may be formed for overlapping beams at high precision and controlling a position to start and finish laser irradiation. The marker may be formed over a substrate at the same time as an amorphous semiconductor film.

It is to be noted that a laser may be a gas laser, a solid state laser, a copper vapor laser, a gold vapor laser and the like capable of continuous oscillation or pulsed oscillation. The gas laser includes an excimer laser, an Ar laser, a Kr laser, a He—Cd laser and the like while the solid state laser includes a YAG laser, a YVO₄ laser, a YLF laser, a YAlO₃ laser, a Y₂O₃ laser, a glass laser, a ruby laser, an alexandrite laser, a Ti:sapphire laser and the like.

The laser crystallization may be performed by a pulse laser at a repetition rate of 0.5 MHz or more, which is a drastically higher range of repetition rates than a generally used range of repetition rates of several ten to several hundred Hz. It is said that the time between irradiation of laser light and solidification of the semiconductor film is several ten to several hundred nsec in a pulse laser. Hence, the semiconductor film can be irradiated with the following pulse of the laser light during the period from melting the semiconductor film by the preceding pulse and solidification of the semiconductor film by using the foregoing range of repetition rate. Since solid-liquid interface can be continuously moved in the semiconductor film, a semiconductor film having crystal grains that have grown continuously in the scanning direction of the laser beam is formed. Specifically, an aggregate of crystal grains having widths of 10 to 30 μm in the scanning direction and widths of 1 to 5 μm in the direction perpendicular to the scanning direction can be formed. By forming crystal grains of single crystal extended long along the scanning direction, a semiconductor film which has almost no crystal boundary at least in a channel direction of a TFT can be formed.

The semiconductor film may be irradiated with laser light in an inert gas atmosphere such as rare gas or nitrogen. Accordingly, roughness of a surface of the semiconductor film due to laser irradiation can be prevented, and variation of a threshold voltage due to variation of interface state densities can be prevented.

An amorphous semiconductor film may be crystallized by the combination of thermal treatment and laser light irradiation, or one of thermal treatment and laser light irradiation may be performed a plurality of times.

In this embodiment mode, a crystalline semiconductor film is formed by forming an amorphous semiconductor film over the base film 101b and crystallizing the amorphous semiconductor film. As the amorphous semiconductor film, amorphous silicon formed using a reaction gas of SiH₄ and H₂ is used. In this embodiment mode, the base film 101a, the base film 101b, and the amorphous semiconductor film are continuously formed by changing a reaction gas without breaking the vacuum in the same chamber at the same temperature of 330° C.

After removing an oxide film formed over the amorphous semiconductor film, an oxide film is formed with a thickness of 1 to 5 nm by UV light irradiation in an oxygen atmosphere, a thermal oxidization method, treatment by ozone water containing hydroxy radical or hydrogen peroxide solution, or the like. In this embodiment mode, Ni is used as an element for promoting crystallization. An aqueous solution containing 10 ppm of Ni acetate is applied by a spin coating method.

In this embodiment mode, after performing thermal treatment by an RTA method at 750° C. for three minutes, the oxide film formed over the semiconductor film is removed and laser irradiation is applied. The amorphous semiconductor film is crystallized by the aforementioned crystallization treatment to form a crystalline semiconductor film.

In the case of performing crystallization using a metal element, a gettering step is performed for reducing or removing the metal element. In this embodiment mode, the metal element is captured using the amorphous semiconductor film as a gettering sink. First, an oxide film is formed over the crystalline semiconductor film by UV light irradiation in an oxygen atmosphere, thermal oxidation, treatment with ozone water containing hydroxyl radical, treatment with hydrogen peroxide, or the like. Further, an amorphous semiconductor film is formed with a thickness of 50 nm by a plasma CVD method (with a condition of this embodiment mode as 350 W and 35 Pa).

After that, thermal treatment is performed at 744° C. for three minutes by an RTA method to reduce or remove the metal element. The thermal treatment may be performed in a nitrogen atmosphere. Then, the amorphous semiconductor film as a gettering sink and an oxide film formed over the amorphous semiconductor film are removed by hydrofluoric acid and the like, thereby a crystalline semiconductor film 102 from which the metal element is reduced or removed can be obtained (see FIG. 2A). In this embodiment mode, the amorphous semiconductor film as a gettering sink is removed by TMAH (Tetramethyl Ammonium Hydroxide).

The semiconductor film formed in this manner may be doped with a slight amount of impurity elements (boron or phosphorus) for controlling a threshold voltage of a thin film transistor. This doping of impurity elements may be performed against an amorphous semiconductor film before crystallization. When the amorphous semiconductor film is doped with impurity elements, the impurities can be activated by thermal treatment for crystallization later. Further, a defect and the like generated at the doping can be improved as well.

Subsequently, the crystalline semiconductor film 102 is patterned using a mask. In this embodiment mode, after removing the oxide film formed over the crystalline semiconductor film 102, an oxide film is newly formed. Then, a photo mask is formed and patterned by a photolithography method, thereby a semiconductor layer 103, a semiconductor layer 104, a semiconductor layer 105, and a semiconductor layer 106 are formed.

An etching process at the patterning may be either plasma etching (dry etching) or wet etching. In the case of processing a large area substrate, plasma etching is more preferable. As an etching gas, a fluorine-based gas a chlorine-based gas such as CF₄, NF₃, Cl₂, or BCl₃ is used, to which an inert gas such as He and Ar may be appropriately added. In the case of employing an etching process by atmospheric pressure electric discharge, local electric discharge can be realized, which does not require a mask layer to be formed over an entire surface of the substrate.

In this embodiment mode, a conductive layer for forming a wiring layer or an electrode layer, a mask layer for forming a predetermined pattern, or the like may be formed by a method where a pattern can be selectively formed, such as a droplet discharge method. In the droplet discharge method (also referred to as an inkjet method according to the system thereof), a predetermined pattern (a conductive layer, an insulating layer, and the like) can be formed by selectively discharging (ejecting) liquid of a composition prepared for a specific purpose. In this case, a process for controlling wettability and adhesion may be performed in a region to be formed thereon. Additionally, a method for transferring or describing a pattern, for example, a printing method (a method for forming a pattern such as a screen printing, and an offset printing) or the like can be used.

In this embodiment mode, a resin material such as an epoxy resin, an acrylic resin, a phenol resin, a novolac resin, a melamine resin, or an urethane resin is used as a mask. Alternatively, the mask may also be made of an organic material such as benzocyclobutene, parylene, flare and polyimide having a light transmitting property; a compound material formed by polymerization of siloxane polymers or the like; a composition material containing a water-soluble homopolymer and a water-soluble copolymer; and the like. In addition, a commercially available resist material containing a photosensitive agent may also be used. For example, it is possible to use a typical positive resist including a novolac resin and a naphthoquinonediazide compound that is a photosensitive agent; a base resin that is a negative resist, diphenylsilanediol, an acid generating material, and the like. The surface tension and the viscosity of any material are appropriately adjusted by controlling the solvent concentration, adding a surfactant, or the like, when a droplet discharge method is used.

A gate insulating layer 107 covering the semiconductor layer 103, the semiconductor layer 104, the semiconductor layer 105, and the semiconductor layer 106 is formed. The gate insulating layer 107 is formed of an insulating film containing silicon with a thickness of 10 to 150 nm by a plasma CVD method or a sputtering method. The gate insulating layer 107 may be formed of a known material such as an oxide material or nitride material of silicon, typified by silicon nitride, silicon oxide, silicon oxynitride, and silicon nitride oxide and may be stacked layers or a single layer. Further, the insulating layer may have a stack of layers including a silicon nitride film, a silicon oxide film, and a silicon nitride film, or a single layer or a stack of two layers of a silicon oxynitride film may be employed as well. More preferably, a silicon nitride film with a dense film quality is used. A thin silicon oxide film may be formed between the semiconductor layer and the gate insulating layer with a thickness of 1 to 100 nm, preferably 1 to 10 nm, and more preferably 2 to 5 nm. The semiconductor surface of the semiconductor region is oxidized by a GRTA (gas rapid thermal annealing) method, an LRTA (lamp rapid thermal annealing) method, or the like and a thermal oxide film is formed, thereby forming a silicon oxide film with a thin thickness. Note that a rare gas element such as argon may be added to a reactive gas and be mixed into an insulating film to be formed in order to form a dense insulating film having little gate leak current at low film formation temperature. In this embodiment mode, a silicon oxynitride film is formed to a thickness of 115 nm as the gate insulating layer 107.

Subsequently, a first conductive film 108 having a thickness of 20 to 100 nm and a second conductive film 109 having a thickness of 100 to 400 nm, each of which serves as a gate electrode layer are stacked over the gate insulating layer 107 (FIG. 2B). The first conductive film 108 and the second conductive film 109 can be formed by a known method such as a sputtering method, a vapor deposition method, or a CVD method. The first conductive film 108 and the second conductive film 109 may be formed of an element selected from tantalum (Ta), tungsten (W), titanium (Ti), molybdenum (Mo), aluminum (Al), copper (Cu), chromium (Cr), and neodymium (Nd), or an alloy material or compound material having the aforementioned element as a main component. A semiconductor film typified by a polycrystalline silicon film that is doped with an impurity element such as phosphorus or an AgPdCu alloy may be used as the first conductive film 108 and the second conductive film 109. The conductive film is not limited to the two-layer structure, and, for example, may have a three-layer structure in which a tungsten film with a thickness of 50 nm, an alloy film of aluminum and silicon (Al—Si) with a thickness of 500 nm, and a titanium nitride film with a thickness of 30 nm are sequentially stacked. In the case of the three-layer structure, tungsten nitride may be used in stead of tungsten of the first conductive film; an alloy film of aluminum and titanium (Al—Ti) may be used in stead of an alloy film of aluminum and silicon (Al—Si) of the second conductive film; or a titanium film may be used in stead of a titanium nitride film of a third conductive film. Further, a single-layer structure may also be used. In this embodiment mode, tantalum nitride (TaN) with a thickness of 30 nm is used for the first conductive film 108 and tungsten (W) with a thickness of 370 nm is used for the second conductive film 109.

Then, a mask 110a, a mask 110b, a mask 110c, a mask 110d, and a mask 110f using a resist is formed by a photolithography method and the first conductive film 109 and the second conductive film 108 are patterned to form a first gate electrode layer 121, a first gate electrode layer 122, a first gate electrode layer 124, a first gate electrode layer 125, and a first gate electrode layer 126, and then a conductive layer 111, a conductive layer 112, a conductive layer 113, a conductive layer 115, and a conductive layer 116 are formed (see FIG. 2C). The first gate electrode layer 121, the first gate electrode layer 122, the first gate electrode layer 124, the first gate electrode layer 125, and the first gate electrode layer 126, and then the conductive layer 111, the conductive layer 112, the conductive layer 113, the conductive layer 115, and the conductive layer 116 can be etched to have a desired tapered shape by appropriately adjusting an etching condition (electric power applied to a coil-shaped electrode layer, electric power applied to an electrode layer on a substrate side, electrode temperature on a substrate side, or the like) by an ICP (Inductively Coupled Plasma) etching method. Further, an angle and the like of the tapered shape can be controlled by the shapes of the mask 110a, the mask 110b, the mask 110d, and the mask 110f. As an etching gas, a chlorine-based gas typified by Cl₂, BCl₃, SiCl₄, CCl₄, or the like, a fluorine-based gas typified by CF₄, CF₅, SF₆, NF₃, or the like, or O₂ can be appropriately used. In this embodiment mode, the second conductive film 109 is etched using an etching gas containing CF₅, Cl₂, and O₂ and then the first conductive film 108 is continuously etched using an etching gas containing CF₅ and Cl₂.

Subsequently, the conductive layer 111, the conductive layer 112, the conductive layer 114, the conductive layer 115, and the conductive layer 116 are patterned using the mask 110a, the mask 110b, the mask 110c, the mask 110d, the mask 110e, and the mask 110f. At this time, the conductive layer is etched with an etching condition of high selection ratio toward the second conductive film 109 which forms the conductive layer and the first conductive film 108 which forms the first gate electrode layer. By this etching, the conductive layer 111, the conductive layer 112, the conductive layer 113, the conductive layer 114, the conductive layer 115, and the conductive layer 116 are etched to form a second gate electrode layer 131, a second gate electrode layer 132, a second gate electrode layer 134, a second gate electrode layer 135, and a second gate electrode layer 136. In this embodiment mode, the conductive layer 163 has a tapered shape of which tapered angle is larger than that of the first gate electrode layer 121, the first gate electrode layer 122, the first gate electrode layer 124, the first gate electrode layer 125, and the first gate electrode layer 126. It is to be noted that the tapered angle is an angle of a side surface relatively to the surface of the first gate electrode layer, the second gate electrode layer, and the conductive layer. Accordingly, when the tapered angle is increased to 90°, the conductive layer has a perpendicular side and no tapered shape. In this embodiment mode, the second gate electrode is formed using an etching gas of Cl₂, SF₆, and O₂.

In this embodiment mode, each of the first gate electrode layer, the conductive layer, and the second gate electrode layer is formed to have a tapered shape, therefore, both of the two gate electrode layers have tapered shapes. However, the invention is not limited to this and one of the gate electrode layers may have a tapered shape while the other has a perpendicular side formed by anisotropic etching. As described in this embodiment mode, the tapered angles may be different or the same between the stacked gate electrode layers. With a tapered shape, coverage of a film to be stacked thereover is improved and a defect is reduced, which leads to improve reliability.

By the aforementioned steps, a gate electrode layer 117 formed of the first gate electrode layer 121 and the second gate electrode layer 131, and a gate electrode layer 118 formed of the first gate electrode layer 122 and the second gate electrode layer 132 can be formed in a peripheral driver circuit region 204, a gate electrode layer 127 formed of the first gate electrode layer 124 and the second gate electrode layer 134, a gate electrode layer 128 formed of the first gate electrode layer 125 and the second gate electrode layer 135 and, a gate electrode layer 129 formed of the first gate electrode layer 126 and the second gate electrode layer 136 can be formed in a pixel portion 206 (see FIG. 2D). In this embodiment mode, the gate electrode layers are formed by dry etching, however, wet etching may be employed as instead.

The gate insulating layer 107 may be etched to some extent and reduced in thickness by an etching step for forming the gate electrode layers.

By forming a width of the gate electrode layer thin, a thin film transistor capable of high speed operation can be formed. Two methods for forming a width of the gate electrode layer in a channel direction thin are described below.

A first method is to form a mask for a gate electrode layer, slim the mask in a width direction by etching, ashing and the like, and then forming a mask with a thinner width. By using a mask with a thinner width, the gate electrode layer can be formed in a shape with a thinner width.

A second method is to form a normal mask and then form a gate electrode layer using the mask. Then, the gate electrode layer is etched in the side in a width direction to be thinned. Accordingly, a gate electrode layer with a thinner width can be formed. By the aforementioned steps, a thin film transistor with a short channel length can be formed, which can realize a thin film transistor capable of high speed operation.

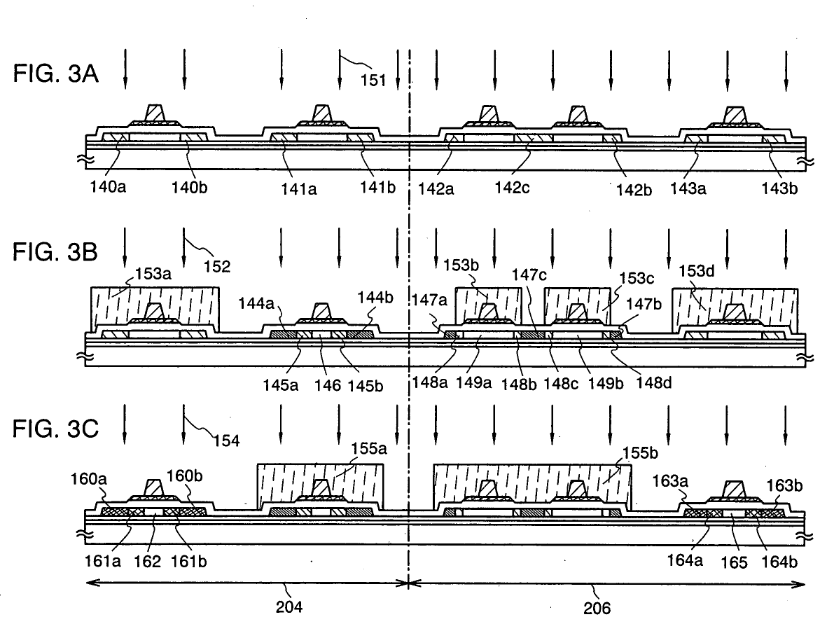

Next, impurity element 151 which imparts n-type conductivity is added using the gate electrode layer 117, the gate electrode layer 118, the gate electrode layer 127, the gate electrode layer 128, and the gate electrode layer 129, as masks to form a first n-type impurity region 140a, a first n-type impurity region 140b, a first n-type impurity region 141a, a first n-type impurity region 141b, a first n-type impurity region 142a, a first n-type impurity region 142b, a first n-type impurity region 142c, a first n-type impurity region 143a, and a first n-type impurity region 143b (see FIG. 3A). In this embodiment mode, doping is performed by using phosphine (PH₃) (PH₃ is diluted with hydrogen (H₂) as the doping gas, the composition rate of PH₃ is 5% in the gas.) as a doping gas containing an impurity element at a gas flow rate of 80 sccm, a beam current of 54 μA/cm, an acceleration voltage of 50 kV, and a dosage of 7.0×10¹³ ions/cm². Here, doping is performed so that the impurity element which imparts n-type conductivity is contained at a concentration of about 1×10¹⁷ to 5×10¹⁸/cm³ in the first n-type impurity region 140a, the first n-type impurity region 140b, the first n-type impurity region 141a, the first n-type impurity region 141b, the first n-type impurity region 142a, the first n-type impurity region 142b, the first n-type impurity region 142c, the first n-type impurity region 143a, and the first n-type impurity region 143b. In this embodiment mode, phosphorus (P) is used as the impurity element which imparts n-type conductivity.

In this embodiment mode, the impurity regions of the regions overlapping the gate electrode layers with the gate insulating layer interposed therebetween are denoted as Lov regions while the impurity regions of the regions which do not overlap the gate electrode layers with the gate insulating layer interposed therebetween are denoted as Loff regions. In FIG. 3A, the impurity regions are shown by hatching and blank spaces. This does not mean that the blank spaces are not added impurity elements, but shows that the concentration distribution of the impurity element in this region reflects the mask and the doping condition. Note that this is the same as in other diagrams of this specification.

Subsequently, masks 153a, 153b, 153c, and 153d which cover the semiconductor layer 103 and a portion of the semiconductor layer 105 and the semiconductor layer 106 are formed. By using the masks 153a, 153b, 153c, 153d, and the second gate electrode layer 132 as masks, an impurity element 152 which imparts n-type conductivity is added to form a second n-type impurity region 144a, a second n-type impurity region 144b, a third n-type impurity region 145a, a third n-type impurity region 145b, a second n-type impurity region 147a, a second n-type impurity region 147b, a second n-type impurity region 147c, a third n-type impurity region 148a, a third n-type impurity region 148b, a third n-type impurity region 148c, and a third n-type impurity region 148d are formed. In this embodiment mode, doping is performed using PH₃ (PH₃ is diluted with hydrogen (H₂) as the doping gas, the composition rate of PH₃ is 5% in the gas.) as a doping gas containing an impurity element at a gas flow rate of 80 sccm, a beam current of 540 μA/cm, an acceleration voltage of 70 kV, and a dosage of 5.0×10¹⁵ ions/cm². Here, doping is performed so that each of the second n-type impurity regions 144a and 144b contains the impurity element at a concentration of about 5×10¹⁹ to 5×10²⁰ /cm³. The third n-type impurity regions 145a and 145b are formed to contain at an approximately the same concentration of the impurity element which imparts n-type conductivity as the third n-type impurity regions 148a, 148b, 148c, and 148d or a little higher concentration. Further, a channel forming region 146 is formed in the semiconductor layer 104, and channel forming regions 149a and 149b are formed in the semiconductor layer 105 (see FIG. 3B).

The second n-type impurity regions 144a, 144b, 147a, 147b, and 147c are high concentration n-type impurity regions which function as sources and drains. On the other hand, the third n-type impurity regions 145a, 145b, 148a, 148b, 148c, and 148d are low concentration impurity regions which function as LDD (Lightly Doped Drain) regions. The n-type impurity regions 145a and 145b overlapped with the first gate electrode layer 122 with the gate insulating layer 107 interposed therebetween are Lov regions which can alleviate an electric field around a drain and suppress a degradation of an on current due to a hot carrier. As a result, a thin film transistor capable of high speed operation can be formed. On the other hand, the third n-type impurity regions 148a, 148b, 148c, and 148d are formed in Loff regions which are not overlapped with the gate electrode layers 127 and 128, therefore, an electric field around a drain can be alleviated and degradation due to a hot carrier injection can be prevented as well as reduce an off current. As a result, a semiconductor device with high reliability and low power consumption can be formed.

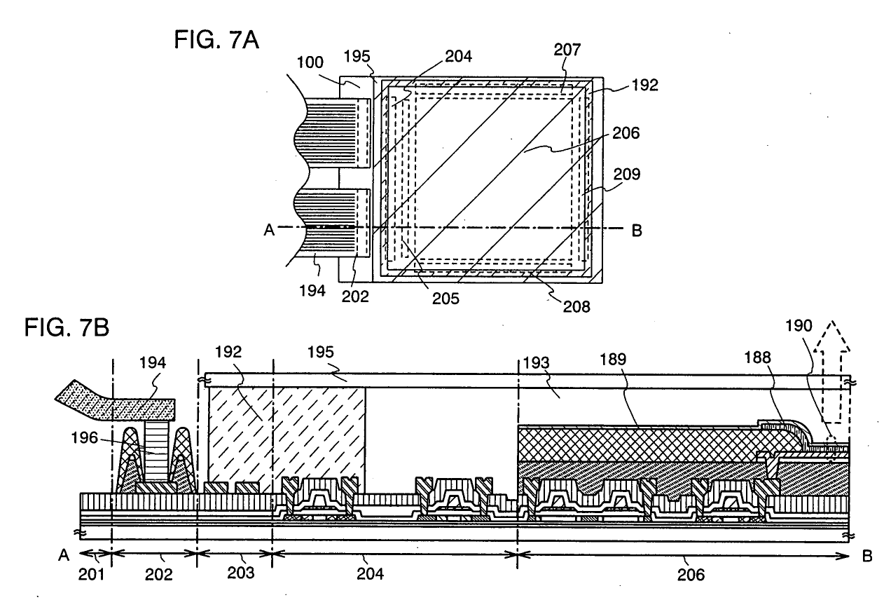

Subsequently, the masks 153a, 153b, 153c, and 153d are removed and masks 155a and 155b to cover the semiconductor layers 103 and 105 are formed. By adding an impurity element 154 which impart p-type conductivity using the masks 155a and 155b, and the gate electrode layers 117 and 129 as masks, first p-type impurity regions 160a, 160b, 163a, 163b, second p-type impurity regions 161a, 161b, 164a, and 164b are formed (see FIG. 7C). In this embodiment mode, boron (B) is used as an impurity element, therefore, doping is performed using diborane (B₂H₆) (B₂H₆ is diluted with hydrogen (H₂) as the doping gas, the composition rate of B₂H₆ is 15% in the gas.) as a doping gas containing an impurity element at a gas flow rate of 70 sccm, a beam current of 180 μA/cm, an acceleration voltage of 80 kV, and a dosage of 2.0×10¹⁵ ions/cm². Here, doping is performed so that the first p-type impurity regions 160a, 160b, 163a, 163b, the second p-type impurity regions 161a, 161b, 164a, and 164b contains the impurity element which imparts p-type conductivity at a concentration of about 1×10²⁰ to 5×10²¹ /cm³. In this embodiment mode, the second p-type impurity regions 161a, 161b, 164a, and 164b are formed by reflecting the shapes of the gate electrode layers 117 and 129 to contain a lower concentration of impurity element than the first p-type impurity regions 160a, 160b, 163a, and 163b in a self-aligned manner. Further, a channel forming region 162 is formed in the semiconductor layer 103 and a channel forming region 165 is formed in the semiconductor layer 106 (see FIG. 3C).

The second n-type impurity regions 144a, 144b, 147a, 147b, and 147c are high concentration n-type impurity regions which function as sources and drains. On the other hand, the second p-type impurity regions 161a, 161b, 164a, and 164b are low concentration impurity regions which function as LDD (Lightly Doped Drain) regions. The second p-type impurity regions 161a, 161b, 164a, and 164b overlapped with the first gate electrode layers 121 and 126 with the gate insulating layer 107 interposed therebetween are Lov regions which can alleviate an electric field around a drain and suppress a degradation of an on current due to a hot carrier.

The masks 155a and 155b are removed by O₂ ashing or using a resist peeling solution, thereby the oxide film is also removed. After that, an insulating film, namely a sidewall may be formed so as to cover sides of the gate electrode layers. The sidewall may be formed of an insulating film containing silicon by a plasma CD method and a low pressure CVD (LPCVD) method.

In order to activate the impurity element, thermal treatment, strong light irradiation, or laser light irradiation may be performed. At the same time as the activation, plasma damage to the gate insulating layer and to an interface between the gate insulating layer and the semiconductor layer can be recovered.

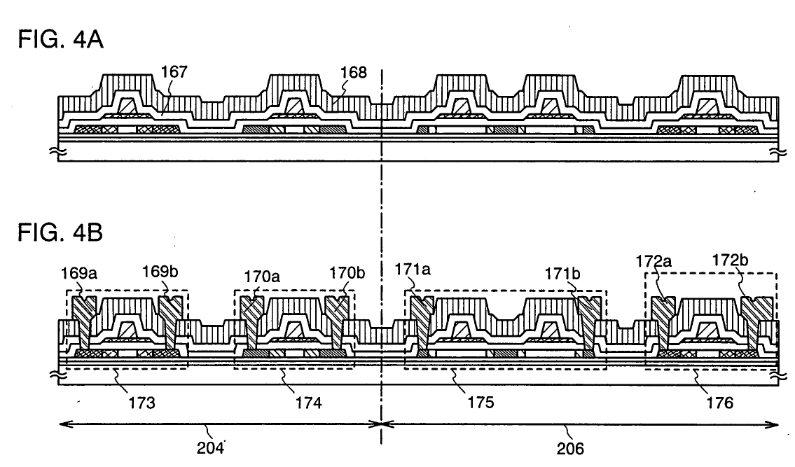

Subsequently, the interlayer insulating layer which covers the gate insulating layer and the gate electrode layer is formed. In this embodiment mode, a stacked-layer structure of the insulating films 167 and 168 is employed (see FIG. 4A). A silicon nitride oxide film is formed as the insulating film 167 with a thickness of 100 nm and an insulating oxynitride film is formed as the insulating film 168 with a thickness of 900 nm to form a stacked-layer structure. Further, a stacked-layer structure of three layers may be employed by forming a silicon oxynitride film with a thickness of 30 nm, a silicon nitride oxide film with a thickness of 140 nm, and a silicon oxynitride film with a thickness of 800 nm. In this embodiment mode, the insulating films 167 and 168 are continuously formed by a plasma CVD method similarly to the base film. The insulating films 167 and 168 are not limited to the above materials and may be a silicon nitride film, a silicon nitride oxide film, a silicon oxynitride film, and a silicon oxide film formed by a plasma CVD method. Alternatively, a single layer structure or a stacked-layer structure of three or more layers of an insulating film containing other silicon may be employed as well.

Further, thermal treatment is performed in a nitrogen atmosphere at 300 to 550° C. for 1 to 12 hours, thereby the semiconductor layer is hydrogenated. Preferably, this step is performed at 400 to 500° C. According to this step, dangling bonds in the semiconductor layer can be terminated by hydrogen contained in the insulating film 167 as an interlayer insulating layer. In this embodiment mode, thermal treatment is performed at 410° C. for one hour.

The insulating films 167 and 168 may be formed of a material selected from aluminum nitride (AlN), aluminum oxynitride (AlON), aluminum nitride oxide containing more nitrogen than oxygen (AlNO), aluminum oxide, diamond-like carbon (DLC), a carbon nitride film (CN) and other substance containing an inorganic insulating material. Further, a siloxane material may be used as well. It is to be noted that a siloxane material corresponds to a resin containing a Si—O—Si bond. Siloxane has a skeleton of a bond of silicon (Si) and oxygen (O). As a substituent, an organic group containing at least hydrogen (for example, an alkyl group and an aromatic carbon hydride) or a fluoro group may be used. Alternatively, an organic group containing at least hydrogen and a fluoro group may be used as a substituent. Further, an organic insulating material may be used such as polyimide, acrylic, polyamide, polyimide amide, resist, benzocyclobutene, or polysilazane. A coated film with a superior planarity formed by a coating method may be used as well.

Subsequently, contact holes (apertures) reaching the semiconductor layer are formed in the insulating films 167 and 168, and the gate insulating layer 107 using a mask of resist. Etching may be performed once or a plurality of times according to a selection ratio of a material to be used. In this embodiment mode, first etching is performed with a condition that a selection ratio can be obtained between the insulating film 167 as a silicon nitride oxide film and the gate insulating layer 107, thereby the insulating film 168 is removed. Then, the insulating film 167 and the gate insulating layer 107 are removed by second etching, apertures reaching the first p-type impurity regions 160a, 160b, 163a and 163b and the second n-type impurity regions 144a, 144b, 147a and 147b as source regions or drain regions, the second n-type impurity regions 144a and 144b, and the second n-type impurity regions 147a, and 147b are formed. In this embodiment mode, the first etching is performed by wet etching while the second etching is performed by dry etching. A fluorine-based solution such as ammonium hydrogen fluoride or a mixture containing ammonium fluoride may be used as an etchant of wet etching. As an etching gas, a chlorine-based gas typified by Cl₂, BCl₃, SiCl₄, CCl₄, or the like, a fluorine-based gas typified by CF₄, SF₆, NF₃, or the like, or O₂ can be appropriately used. Further, an inert gas may be added to an etching gas. As an inert element to be added, one or a plurality of elements selected from He, Ne, Ar, Kr, and Xe can be used.

The conductive film is formed so as to cover the apertures, and the conductive film is etched to form a source electrode layer or a drain electrode layer 169a, a source electrode layer or a drain electrode layer 169b, a source electrode layer or a drain electrode layer 170a, a source electrode layer or a drain electrode layer 170b, a source electrode layer or a drain electrode layer 171a, a source electrode layer or a drain electrode layer 171b, a source electrode layer or a drain electrode layer 172a, and a source electrode layer or a drain electrode layer 172b which are electrically connected to a portion of each source region or drain region are formed. The source electrode layer or drain electrode layer can be formed by forming a conductive film by a PVD method, a CVD method, a vapor deposition method and the like and then etching the conductive film into a desired shape. Further, a conductive layer can be selectively formed in a predetermined place by a droplet discharge method, a printing method, an electrolytic plating method and the like. Further, a reflow method and a damascene method may be used as well. The source electrode layer or drain electrode layer is formed of a metal selected from Ag, Au, Cu, Ni, Pt, Pd, Ir, Rh, W, Al, Ta, Mo, Cd, Zn, Fe, Ti, Si, Ge, Zr, Ba, and the like, or an alloy or a metal nitride thereof. Further, a stacked-layer structure of these may be used. In this embodiment mode, titanium (Ti) is formed to a thickness of 60 nm, titanium nitride is formed to a thickness of 40 nm, aluminum is formed with a thickness of 700 nm, and titanium (Ti) is formed with a thickness of 200 nm to form a layered structure, and then patterned into a desired shape.

Through the above steps, an active matrix substrate can be formed in which a p-channel thin film transistor 173 having a p-type impurity region in a Lov region and an n-channel thin film transistor 174 having an n-channel impurity region in a Lov region can be formed in the peripheral driver circuit region 204, and a multi-channel type n-channel thin film transistor 175 having an n-type impurity region in a Loff region and a p-channel thin film transistor 176 having a p-type impurity region in a Lov region can be formed in the pixel portion 206 (see FIG. 4B).

Then, the active matrix substrate can be used for a light emitting device having a self-luminous element, a liquid crystal display device having a liquid crystal element, and other display devices. Moreover, the active matrix substrate can be used for a semiconductor device such as various processors typified by a CPU (Central Processing Unit) and a card which incorporates an ID chip and the like.

The invention is not limited to this embodiment mode and a thin film transistor may have a single gate structure in which one channel forming region is formed, a double gate structure in which two channel forming regions are formed, or a triple gate structure in which three channel forming regions are formed. Further, a thin film transistor in the peripheral driver circuit region may have a single gate structure, a double gate structure, or a triple gate structure.

It is to be noted that the invention is not limited to the manufacturing method of a thin film transistor described in this embodiment mode, but can also be applied to a top gate type (planar type), a bottom gate type (inversely staggered type), or a dual gate type in which two gate electrode layers are arranged at the top and bottom of a channel region with a gate insulating film interposed therebetween, or other structures.

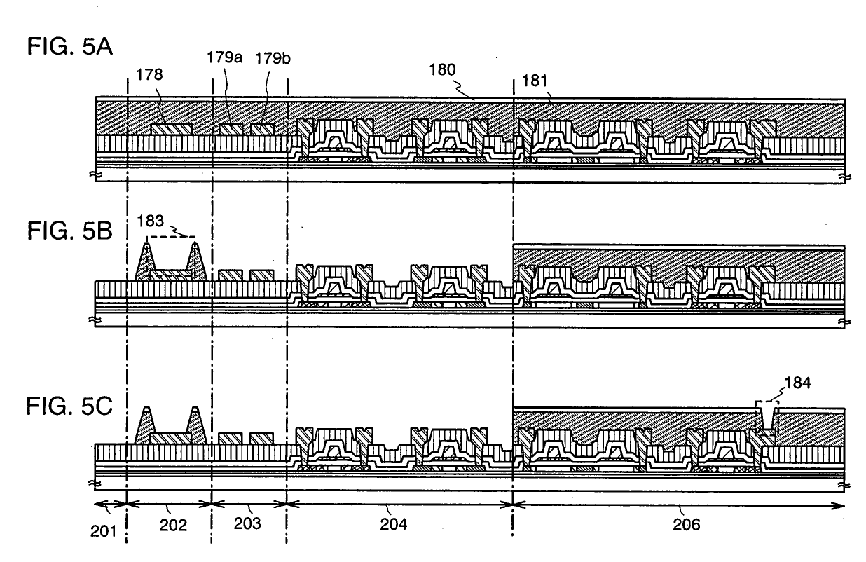

Next, an insulating film 180 is formed as a second interlayer insulating layer, and an interlayer film 181 is formed between the insulating layer 180 and a first electrode layer 396 (FIG. 5A). FIGS. 5A to 5C show manufacturing steps of a display device, in which a region 201 to be cut out by scribing, an external terminal connection region 202 to be attached with an FPC, a wiring region 203 that is a region for leading a wiring in the peripheral portion, a peripheral driver circuit region 204, and a pixel portion 260 are provided. Wirings 179a and 179b are formed in the wiring region 203, and a terminal electrode layer 178 to be connected with an external terminal is formed in the external terminal connection region 202.

The interlayer film 180 and the insulating layer 181 can be formed using a material selected from silicon oxide, silicon nitride, silicon oxynitride, silicon nitride oxide, aluminum nitride (AlN), aluminum oxynitride (AlON), aluminum nitride oxide having more nitrogen content than oxygen content (AlNO), aluminum oxide, diamond like carbon (DLC), a nitrogen-containing carbon (CN) film, a PSG (phosphorus glass), a BPSG (boron phosphorus glass), an alumina film and other substances containing an inorganic insulating material. Further, a siloxane material (inorganic siloxane or organic siloxane) may be employed. A photosensitive or non-photosensitive organic insulating material may be employed, for example, polyimide, acrylic, polyamide, polyimide amide, resist or benzocyclobutene, polysilazane, or a low-k material that is low dielectric can be used.

In this embodiment mode, the insulating layer 181 is preferably formed by a coating method such as spin coating, because a layer that is superior in heat-resistance, insulative property and planarity is needed as the interlayer insulating film for planarization. In this embodiment mode, the interlayer film 180 has a function of improving adhesion between the insulating layer 181 and the first electrode layer 396. The interlayer film 180 is formed by stacking a silicon nitride oxide film and a titanium nitride film over the insulating layer 181. By CVD, a silicon oxynitride film is formed to a thickness of 50 nm and a titanium nitride is formed thereover to a thickness of 10 nm. The interlayer film 180 improves the adhesion between the insulating layer 181 and the first electrode layer 396; thus, the reliability and yield of the display device to be manufactured are also improved.

A coated film of siloxane material is used as the material of the insulating layer 181 in this embodiment mode. The film after baking can be referred to as a silicon oxide film containing an alkyl group (SiOₓ) (x=1, 2 . . . ). This silicon oxide film containing an alkyl group (SiOₓ) can withstand a heat treatment of 300° C. or more.

Dip coating, spraying coating,. a doctor knife, a roll coater, a curtain coater, a knife coater, a CVD method, a vapor deposition method or the like can be used for forming the interlayer film 180 and the insulating layer 181. In addition, the interlayer film 180 and the insulating layer 181 may be formed by a droplet discharging method. A material solution can be saved when the droplet discharging method is adopted. A method capable of transferring or drawing a pattern like the droplet discharging method, for example, a printing method (a method by which a pattern is formed, such as screen printing or offset printing), or the like can also be used.

As shown in FIG. 5B, openings are formed in the interlayer film 180 and the insulating layer 181 that serve as the second interlayer insulating layer. The interlayer film 180 and the insulating layer 181 are required to be etched widely in the connection region (not shown), the wiring region 203, the external terminal connection region 202, the region to be cut out 201 and the like. However, the area of the opening in the pixel portion 206 is still smaller than that in the connection region or the like, and becomes minute. Therefore, a margin of etching condition can be widened by conducting a photolithography process for forming the opening in the pixel portion and a photolithography process for forming the opening in the connection region. Consequently, the yield can be improved. Contact holes in the pixel portion can be formed with high accuracy by widening the margin of the etching condition.

Specifically, openings having large areas are formed in the interlayer film 180 and the insulating film 181 partially formed in the connection region, the wiring region 203, the external terminal connection region 202, the region to be cut out 201 and a portion of the peripheral driver circuit region 204. Thus, masks are formed to cover the interlayer film 180 and the insulating film 181 formed in the pixel portion 206, and in parts of the connection region and the peripheral driver circuit region 204. Parallel-plate RIE (reactive ion etching) system or ICP etching system can be used for etching. Note that the time for etching may be set such that the wiring layer or the first interlayer insulating layer is over etched. Variation in film thickness within the substrate and variation in etching rate can be reduced by setting it such that the wiring layer or the first interlayer insulating layer is over etched. In this way, the opening 183 is formed in the external terminal connection region 202.

A minute opening, in other words, a contact hole, is formed in the interlayer film 180 and the insulating layer 181 in the pixel portion 206 (FIG. 5C). At this time, a mask is formed to cover the pixel portion 206, a portion of the peripheral driver circuit region 204 and the pixel portion 206. The mask is a mask for forming the opening in the pixel portion 206, and is provided with a minute opening in a desired position thereof. A resist mask can, for example, be used as the mask.

The interlayer film 180 and the insulating layer 181 are etched with the parallel-plate RIE (reactive ion etching) system. Note that the time for etching may be set such that the wiring layer or the first interlayer insulating layer is over etched. Variation in film thickness within the substrate and variation in etching rate can be reduced by setting it such that the wiring layer or the first interlayer insulating layer is over etched.

An ICP system may be used for the etching system. Through the above described steps, an opening 184 that reaches the source or drain electrode layer 172a is formed in the pixel portion 206. Further, the source or drain electrode layer can be formed in a region having a large total thickness, in which multiple thin films are stacked. As to a thin film transistor of this embodiment mode, the source or drain electrode layer is preferably formed overt the gate electrode layer. In this case, since the opening 184 is not required to be formed deep, the process for forming the opening can be shortened, and thus the controllability can be enhanced. In addition, an electrode layer to be formed in the opening can be formed with favorable coverage and thus reliability can be enhanced, because the electrode layer does not need to widely cover the opening having a large angle.

This embodiment mode describes the case in which the interlayer film 180 and the insulating layer 181 are etched using the mask covering the wiring region 203, a portion of the external terminal connection region 202, the region to be cut out 201, and a portion of the peripheral driver circuit region 204 and having a desired opening in the pixel portion 206. However, the present invention is not limited thereto. For example, the area of the opening in the connection region is large, and thus the amount to be etched is large. The opening having a large area may be etched plural times. If an opening that is deeper than other openings is formed, etching may be conducted plural times similarly.

In this embodiment mode, the formation of the openings in the interlayer film 180 and the insulating layer 181 are conducted multiple times as shown in FIGS. 5B and 5C; however, only one-time etching may be conducted. In this case, an ICP system is used to conduct etching with ICP power of 7000 W, bias power of 1000 W, pressure of 0.8 Pa, with the use of CF₄ of 240 sccm and O₂ of 160 sccm as the etching gas. The bias power is preferably 1000 to 4000 W. At this time, an advantageous effect that the process can be simplified is obtained, because one-time etching is enough for forming the opening.

Then, a first electrode 396 (also referred to as a pixel electrode) is formed to be in contact with the source or drain electrode layer 172a.

In this embodiment mode, a light-emitting element is used as a display element, and light emitted from the light-emitting element is extracted from the second electrode layer 189 side. Thus, the first electrode layer 185 is reflective. A film containing an aluminum alloy containing at least one or more selected from the group consisting of molybdenum, titanium, and carbon is formed and etched into a desired shape to form the first electrode layer 396. In this embodiment mode, a stack of a titanium nitride film and is used for the interlayer film 180. Since the titanium nitride film is conductive, the interlayer film 180 is patterned at the same time when the first electrode layer 396 is patterned

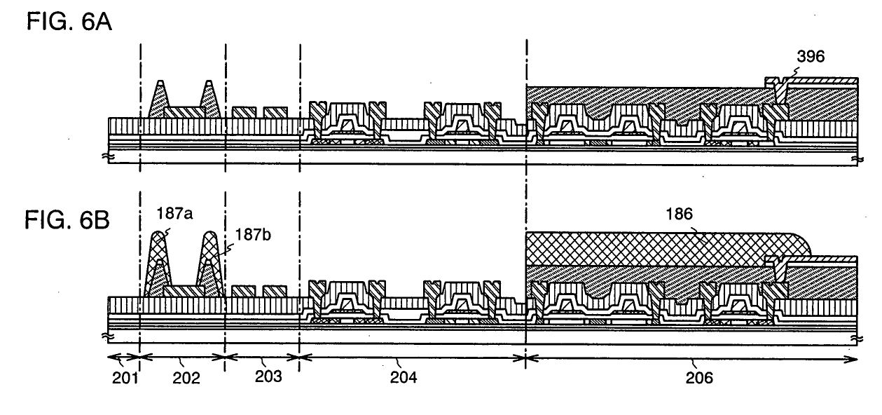

In the present invention, a film containing an aluminum alloy containing at least one or more selected from the group consisting of molybdenum, titanium, and carbon is used for the first electrode layer 396 that is a reflective electrode layer. In this embodiment mode, an Al(Mo) film is used for the first electrode layer 396. The thickness of the first electrode layer 396 may be 20 nm to 200 nm, preferably, 35 nm to 100 nm. In this embodiment mode, the Al(Mo) film is formed to a thickness of 35 nm by sputtering. The film containing an aluminum alloy containing at least one or more selected from the group consisting of molybdenum, titanium, and carbon is hardly crystallized even when subjected to heat treatment, and the surface planarity of the film is good. Further, the reflectance to light in the near visible region is high, and effective light reflection can be carried out. The film containing an aluminum alloy containing at least one or more selected from the group consisting of molybdenum, titanium, and carbon further has an excellent advantage that it is safe for human bodies and environment without toxicity (see FIG. 6A).

In the film containing an aluminum alloy containing at least one or more selected from the group consisting of molybdenum, titanium, and carbon, the content of molybdenum or titanium is preferably more than 7.0 atomic %. Further, in the case where the content of molybdenum or titanium is 20 atomic % or less, it is advantageous since the reflectance to light in the near visible region. In the Al(C) film, the content of carbon in the film is in the range of 0.1 atomic % to 10 atomic %, preferably, less than 1 atomic %. In the film containing an aluminum alloy containing at least one or more selected from the group consisting of molybdenum, titanium, and carbon; even a minute amount of carbon is effective, so that the content of carbon in the film may be 0.3 atomic % or less, further, may be 0.1 atomic % or less.

A transparent conductive film such as an ITO film or an ITSO film may be formed over the first electrode layer 396. An ITSO film may be formed to a thickness of 185 nm by sputtering using a target in which 1 to 10 % of silicon oxide (SiO₂) is added to indium tin oxide under the following conditions: a flow rate of Ar gas: 120 sccm, a flow rate of O₂ gas: 5 sccm, a pressure: 0.25 Pa, and an electric power: 3.2 kW The first electrode layer 369 may be cleaned or polished by CMP or by using a porous material such as polyvinyl alcohol so that the surface thereof is planarized. In addition, after polishing using a CMP method, ultraviolet ray irradiation, oxygen plasma treatment, or the like may be carried out on the surface of the first electrode layer 369.

Heat treatment may be performed after forming the first electrode layer 396. With the heat treatment, moisture included in the first electrode layer 396 is released. Accordingly, degasification or the like is not generated from the first electrode layer 396. Even when a light emitting material which is easily deteriorated by moisture is formed over the first electrode layer, the light emitting material is not deteriorated; therefore, a highly reliable display device can be manufactured. In this embodiment mode, a film containing an aluminum alloy containing at least one or more selected from the group consisting of molybdenum, titanium, and carbon is used for the first electrode layer, so that it is hardly crystallized even when baking is performed, and an amorphous state is kept. Hence, the first electrode layer 396 has high planarity and hardly shorts with the second electrode layer even when a layer containing an organic compound is thin.

In this embodiment mode, photosensitive polyimide is used for the insulating layer 186, 187a and 187b. Further, by forming the insulating layer 186, 187a and 187b using the same material as the insulating layer 181 and the same step, manufacturing cost can be reduced. Moreover, cost can be reduced by using a deposition apparatus, an etching apparatus and the like in common (see FIG. 6B).

An aluminum alloy containing nickel has low resistance to a chemical solution such as a developing solution used in forming the insulating layer 186 serving as a bank which covers a part of the first electrode layer 396. A film containing an aluminum alloy containing at least one or more selected from the group consisting of molybdenum, titanium, and carbon has high resistance. Therefore, a defect such as reduction in the surface or surface roughness is hardly caused in the manufacturing process. Thus, good surface condition can be kept, so that the electroluminescent layer 188 to be formed thereon can be formed stably, and the reliability of the display device can be increased accordingly.

The insulating layer 186 may be formed by using an insulating material such as an inorganic insulating material such as silicon oxide, silicon nitride, silicon oxynitride, aluminum oxide, aluminum nitride, or aluminum oxynitride, acrylic acid, methacrylic acid, a derivative thereof, a heat-resistant high molecular weight material such as polyimide, aromatic polyamide, or polybenzimidazole, or a siloxane resin material. Alternatively, the. insulating layer 186 may be formed by using a photosensitive or non-photosensitive material such as acrylic or polyimide. The insulating layer 186 preferably has a side face with such a shape that a curvature radius continuously changes. Accordingly, coverage of an electroluminescent layer 188 and a second electrode layer 189 formed thereover is improved.

End portions of the interlayer film 180 and the insulating film 181 that have been processed to have steps by patterning are steeply inclined. Therefore, the coverage of the second electrode layer 189 stacked thereon is not favorable. Correspondingly, the steps in the periphery of the opening is covered with the insulating layer 186 to be gradual, thereby improving the coverage of the second electrode layer 189 to be stacked thereon. In the connection region, a wiring layer to be formed through the same steps and from the same material as the second electrode layer is electrically connected to the wiring layer that is formed through the same steps and from the same material as the gate electrode layer.

Further, in order to improve the reliability, it is preferable to perform degasification of the substrate by vacuum heating before forming the electroluminescent layer 188. For example, it is preferable to perform thermal treatment for removing gas contained in the substrate in a low pressure atmosphere or an inert gas atmosphere at 200 to 400° C. or preferably 250 to 350° C. Further, it is preferable to form the electroluminescent layer 188 by a vacuum vapor deposition method or a droplet discharge method under a reduced pressure without exposing the substrate to air. By this thermal treatment, moisture contained or attached to a conductive film to be the first electrode layer or an insulating layer (bank) can be discharged. This thermal treatment can be combined with a prior thermal step as long as the substrate can be transferred in a vacuum chamber without breaking the vacuum. Therefore, the prior thermal treatment is only required to be performed once after forming an insulating layer (bank). Here, by forming the interlayer insulating film and insulating layer (bank) using a highly heat resistant substance, thermal treatment step can be sufficiently performed for improving the reliability.

The electroluminescent layer 188 is formed over the first electrode layer 396. Although only one pixel is shown in FIGS. 1A and 1B, electroluminescent layers corresponding to each color of R (red), G (green) and B (blue) are separately formed in this embodiment mode. The electroluminescent layer 188 may be manufactured as shown in Embodiment Mode 1; both an organic compound and an inorganic compound are mixed on the first electrode layer 396, so that a layer having functions of a high carrier injection property and a high carrier transporting property which can not be obtained when only one kind of the compounds is used.

The materials (a low or high molecular weight material, or the like), which show luminescence of each color red (R), green (G), and blue (B), can also be formed by a droplet discharge method.

Subsequently, the second electrode layer 189 formed of a conductive film is provided over the electroluminescent layer 188. As the second electrode layer 189, a material having a low work function (Al, Ag, Li, Ca, or an alloy thereof such as MgAg, MgIn, AlLi, and a compound CaF₂ or calcium nitride) may be used. In this manner, a light emitting element 190 formed of the first electrode layer 185, the electroluminescent layer 188, and the second electrode layer 189 is formed.

In the display device of this embodiment mode shown in FIG. 7B, light emitted from the light emitting element 190 is emitted from the second electrode layer 189 side to transmit in a direction of an arrow in FIG. 7B.

It is effective to provide a passivation film so as to cover the second electrode layer 189. The passivation film may be formed of a single layer or stacked layers of an insulating film containing silicon nitride, silicon oxide, silicon oxynitride (SiON), silicon nitride oxide (SiNO), aluminum nitride (AlN), aluminum oxynitride (AlON) aluminum nitride oxide (AlNO) containing more amount of nitrogen than oxygen, aluminum oxide, diamond-like carbon (DLC), or a carbon nitride film (CN). Moreover, a siloxane material may be used as well.

At this time, it is preferable to form a passivation film with favorable coverage, for which a carbon film, particularly a DLC film is effectively used. A DLC film which can be deposited in the temperature range from a room temperature to 100° C. can be easily formed above the electroluminescent layer 188 with low heat resistance. A DLC film can be formed by a plasma CVD method (typically an RF plasma CVD method, a microwave CVD method, an electron cyclotron resonance (ECR) CVD method, a heat filament CVD method and the like), a combustion method, a sputtering method, an ion beam vapor deposition method, a laser vapor deposition method and the like. As a reactive gas, a hydrogen gas and a carbon hydride based gas (for example, CH₄, C₂H₂, C₆H₆ and the like) are used to be ionized by glow discharge and the ions are accelerated to impact against a cathode to which a negative self-bias voltage is applied. Further, a CN film may be formed using a C₂H₂ gas and a N₂ gas as a reactive gas. A DLC film has a high blocking effect against oxygen, thereby oxidization of the electroluminescent layer 188 can be suppressed. Therefore, a problem in that the electroluminescent layer 188 is oxidized before a subsequent sealing step can be prevented.

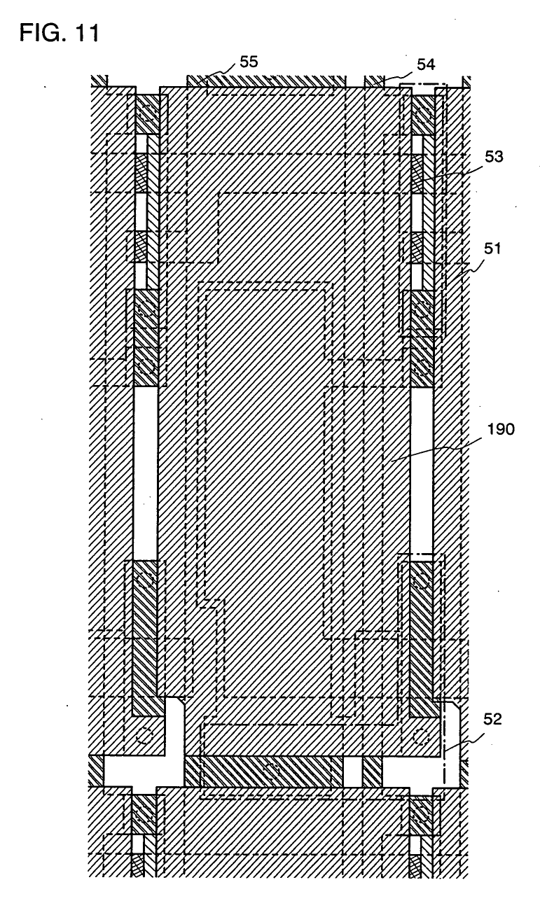

A top view of a pixel portion in a display device manufactured in this embodiment mode is shown in FIG. 11. In FIG. 11, a pixel includes a thin film transistor 51, a thin film transistor 52, a light emitting element 190, a gate wiring layer 53, a source and drain wiring layer 54, and a power line 55.

In this manner, by firmly fixing a sealing substrate 195 and the substrate 100 over which the light emitting element 190 is formed with a sealing material 192, the light emitting element is sealed (see FIGS. 7A and 7B). In the display device of the invention, the sealing material 192 and the insulating layer 186 are formed apart so as not to contact each other. By forming the sealing material 192 and the insulating layer 186 apart from each other, even when an insulating material using an organic material having high moisture absorbing property is used for the insulating layer 186, moisture does not easily enter, which can prevent deterioration of the light emitting element and improve the reliability of the display device. As the sealing material 192, it is typically preferable to use a visible light curable resin, an ultraviolet ray curable resin, or a heat curable resin. For example, a bisphenol-A liquid resin, a bisphenol-A solid resin, a bromine-containing epoxy resin, a bisphenol-F resin, a bisphenol-AD resin, a phenol resin, a cresol resin, a novolac resin, a cycloaliphatic epoxy resin, an Epi-Bis type (Epichlorohydrin-Bisphenol) epoxy resin, a glycidyl ester resin, a glycidyl amine resin, heterocyclic epoxy resin, and a modified epoxy resin. It is to be noted that a region surrounded by a sealing material may be filled with a filling material 193, which may be charged with nitrogen by sealing in a nitrogen atmosphere. As a bottom emission type is employed in this embodiment mode, the filling material 193 is not required to transmit light. However, in the case of extracting light through the filling material 193, the filling material is required to transmit light. Typically, a visible light curable, ultraviolet ray curable, or heat curable epoxy resin may be used. By the aforementioned steps, a display device having a display function using a light emitting element of this embodiment mode is completed. Further, the filling material may be filled in the display device by dropping a filling material in a liquid state.

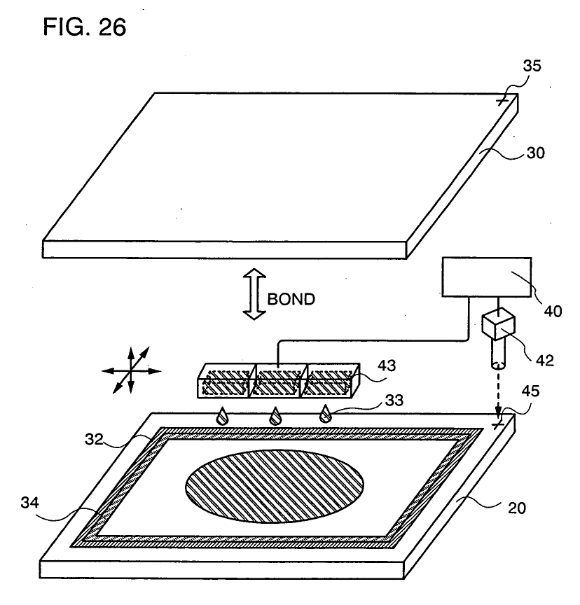

An instillation method using a dispenser method is described with reference to FIG. 26. The instillation method shown in FIG. 26 includes a control device 40, an imaging means 42, a head 43, a filling material 33, a marker 35, a marker 45, a barrier layer 34, a sealing material 32, a TFT substrate 30, and a counter substrate 20. The filling material 33 is dropped once or a plurality of times from the head 43 in a closed loop formed by the sealing material 32. In the case where the filling material has high viscosity, the filling material is continuously discharged and attached to a forming region without a break. In the case where the filling material has low viscosity, the filling material is intermittently discharged and dropped as shown in FIG. 26. At this time, the barrier layer 34 may be provided to prevent that the sealing material 32 reacts the filling material 33. Subsequently, the substrates are attached to each other in vacuum and then cured by ultraviolet ray to be filled with the filling material. As the filling material, a substance having a moisture absorbing property may be used to obtain a further moisture absorbing effect, thereby deterioration of the element can be prevented.

A drying agent is provided in an EL display panel to prevent deterioration by moisture. In this embodiment mode, a drying agent is provided in a depression portion formed so as to surround the pixel portion in the sealing substrate not to hinder a thin design. Further, a drying agent is also formed in a region corresponding to a gate wiring layer so that a moisture absorbing area becomes wide, by which moisture can be effectively absorbed. Further, a drying agent is formed over a gate wiring layer which does not emit light, therefore, light extraction efficiency is not decreased either.

It is to be noted that a light emitting element is sealed by a glass substrate, however, any one of a method for mechanically sealing the light emitting element by a cover material, a method for sealing the light emitting element by a heat curable resin or an ultraviolet ray curable resin, or a method for sealing the light emitting element by a thin film having a high barrier property such as a metal oxide, a metal nitride, and the like may be used. As the cover material, glass, ceramics, plastic, or metal can be used, however, a material which transmits light is required to be used in the case where light is emitted to a cover material side. The cover material and the substrate over which the light emitting element is formed are attached using a sealing material such as a heat curable resin or an ultraviolet ray curable resin by curing the resin using heat treatment or ultraviolet ray irradiation treatment, thereby a sealed space is formed. It is also effective to provide a moisture absorbing material typified by barium oxide in this sealed space. This moisture absorbing material may be provided in contact with the sealing material, over or in the periphery of the bank so as not to prevent the light from the light emitting element. Further, the space formed between the cover material and the substrate over which the light emitting element is formed may be filled with a heat curable resin or an ultraviolet ray curable resin. In this case, it is effective to add an absorbing material typified by barium oxide in the heat curable resin or the ultraviolet ray curable resin.

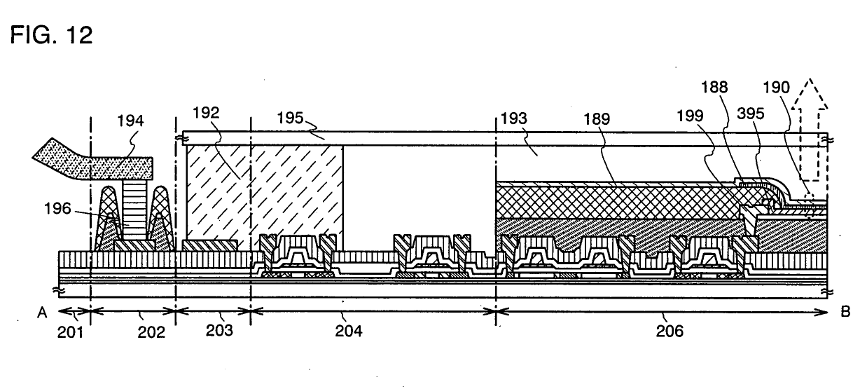

FIG. 12 shows an example of a display device manufactured in this embodiment mode, which is shown in FIGS. 1A and 1B, in which the source electrode layer or the drain electrode layer are not connected by directly contacting each other but through a wiring layer. In the display device in FIG. 12, the source electrode layer or the drain electrode layer of a thin film transistor for driving a light emitting element is electrically connected to a first electrode layer 395. Further, in FIG. 12, the first electrode layer 395 is partially stacked over a wiring 199 to be in contact. Alternatively, the first electrode layer 395 is formed first, and the wiring layer 199 may be formed on the first electrode layer 395 to be in contact.

In this embodiment mode, an FPC 194 is connected to a terminal electrode layer 178 through an anisotropic conductive layer 196 in an external terminal connecting region 202 for external electrical connection. As shown in FIG. 7A which is a top view of a display device, a display device manufactured in this embodiment mode includes peripheral driver circuit regions 207 and 208 each including a scan line driver circuit in addition to a peripheral driver circuit region 204 and a peripheral driver circuit region 209 including a signal line driver circuit.

The aforementioned circuit is formed in this embodiment mode, however, the invention is not limited to this. An IC chip may be mounted by the aforementioned COG method or a TAB method as the peripheral driver circuit. Further, each of the gate line driver circuit and the source line driver circuit may be provided in a single number or a plurality of numbers.

In the display device of the invention, a driving method for an image display is not particularly limited, and a dot sequential driving method, a line sequential driving method, an area sequence driving method and the like may be used. Typically, the line sequence driving method may be used, and a time division gray scale driving method and an area gray scale driving method may be appropriately used as well. Further, a video signal inputted to the source line of the display device may be an analog signal or a digital signal. The driver circuit and the like may be appropriately designed according to the video signal.

Further, a display device using a digital video signal employs a constant voltage (CV) or a constant current (CC) video signal inputted to a pixel. The constant voltage (CV) video signal includes a constant voltage applied to a light emitting element (CVCV) and a constant current applied to a light emitting element (CVCC). Further, the constant current (CC) video signal includes a constant voltage applied to a light emitting element (CCCV) and a constant current applied to a light emitting element (CCCC).

By applying the invention, a display device with high reliability can be manufactured through simplified steps. Therefore, a display device with high definition and image quality can be manufactured at low cost with high yield.

### EMBODIMENT MODE 3

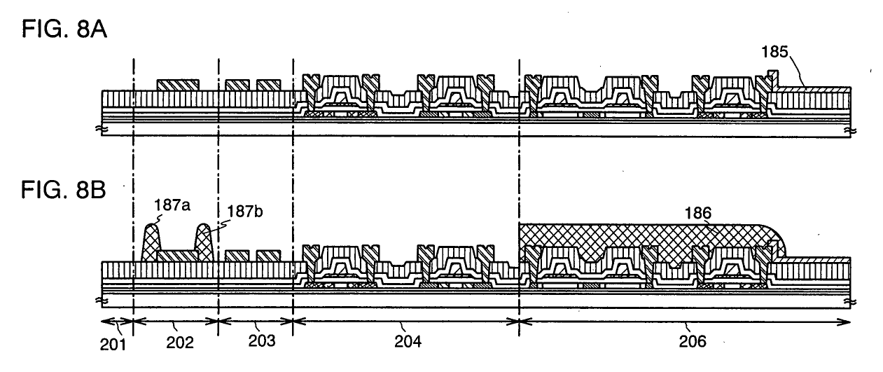

Embodiment Mode according to the present invention is described with reference to FIGS. 8A to 10. This embodiment mode will describe an example in which a second interlayer insulating film is not formed in the display device manufactured in Embodiment Mode 1. Therefore, the description of the same portions and the portions having the same function is omitted.

As shown in Embodiment Mode 1, p-channel thin film transistors 173 to 176 and an insulating film 168 are formed over a substrate 100. A source or drain electrode layer to be connected to a source or drain region of a semiconductor layer is formed in each thin film transistor. A first electrode layer 395 is formed to be in contact with a source or drain electrode layer 172b in the p-channel thin film transistor 176 provided in a pixel portion 206 (FIG. 8A).

The first electrode layer 395 serves as a pixel electrode, and may be formed from the same material in the same process as the first electrode layer 395 in Embodiment Mode 2. In this embodiment mode, light is extracted through the first electrode layer as in Embodiment Mode 1, and thus an Al(Mo) film that serves as a reflective electrode is used for the first electrode layer 395 and patterned.

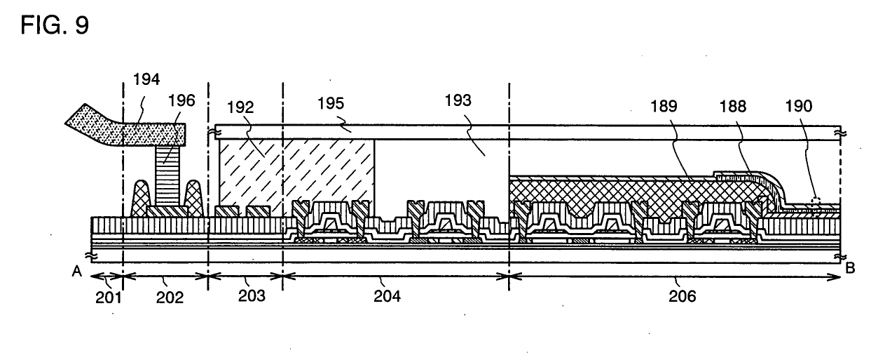

An insulating layer 186 is formed to cover an edge portion of the first electrode layer 395 and the thin film transistors (FIG. 8B). Acrylic is used for the insulating layer 186 in this embodiment mode. An electroluminescent layer 188 is formed over the first electrode layer and a second electrode layer 189 is stacked thereover to obtain a light-emitting element 190. The substrate 100 is attached to a sealing substrate 195 by a sealing material 192, and a filler 193 fills a display device (FIG. 9). In a display device of the present invention, the sealing material and the insulating layer 186 are formed separately so as not contact each other. When the sealing material and the insulating layer 186 are formed separately, moisture hardly enters a light emitting element even when an insulating mat of a highly hygroscopic organic material is used for the insulating layer 186; thus, degradation of a light emitting element can be prevented and the reliability of the display device can be improved.

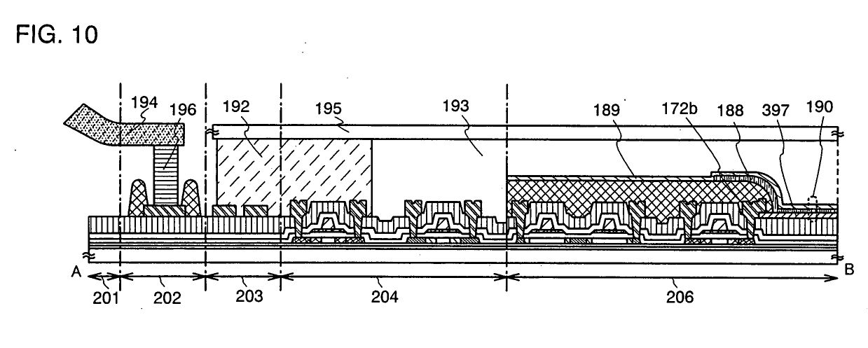

In the display device shown in FIG. 10, the first electrode layer 395 is selectively formed over the insulating film 168 before forming the source or electrode layer 172b to be connected to the p-channel thin film transistor 176. In this case, the source or drain electrode layer 172b is connected to the first electrode layer 395 by stacking the source or drain electrode layer 172b over the first electrode layer. When the first electrode layer 395 is formed before forming the source or drain electrode layer 172b, the first electrode layer 395 can be formed in a flat region; therefore, there are advantages of good coverage since it is possible to sufficiently conduct a polishing treatment such as CMP.

By applying the present invention, a highly reliable display device can be manufactured. Therefore, a display device can be manufactured with high definition and high image quality.

### EMBODIMENT MODE 4

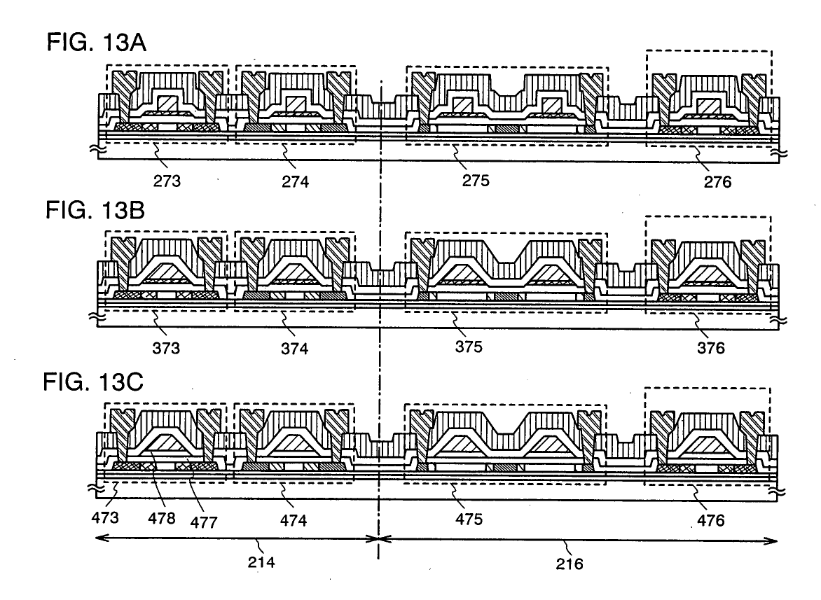

An embodiment mode of the invention is described with reference to FIGS. 13A to 13C. In this embodiment mode, a description is made on an example where a gate electrode layer of a thin film transistor has a different structure in the display device manufactured according to Embodiment Mode 1. Therefore, description on the same portion or a portion having a similar function will not be repeated.

Each of FIGS. 13A to 13C shows a manufacturing step of a display device, which corresponds to the display device of Embodiment Mode 1 shown in FIG. 4B.

In FIG. 13A, thin film transistors 273 and 274 are provided in a peripheral driver circuit region 214, and thin film transistors 275 and 276 are provided in a pixel portion 216. A gate electrode layer of the thin film transistor in FIG. 13A is formed of stacked layers of two conductive films, in which a top gate electrode layer is patterned to have a thinner width than a bottom gate electrode layer. The bottom gate electrode layer has a tapered shape while the top gate electrode layer does not have a tapered shape. In this manner, a gate electrode layer may have a tapered shape or a shape of which side angle is almost perpendicular without being tapered.

In FIG. 13B, thin film transistors 373 and 374 are provided in the peripheral driver circuit region 214, and thin film transistors 375 and 376 are provided in the pixel portion 216. A gate electrode layer of the thin film transistor in FIG. 13B is also formed of stacked layers of two conductive films, in which each of top and bottom gate electrode layers has a continuous tapered shape.

In FIG. 13C, thin film transistors 473 and 474 are provided in the peripheral driver circuit region 214, and thin film transistors 475 and 476 are provided in the pixel portion 216. A gate electrode layer of the thin film transistor in FIG. 13C has a single layer structure and a tapered shape. In this manner, the gate electrode layer may have a single layer structure.

A display device in FIG. 13C a gate insulating layer includes a gate insulating layer 477 and another gate insulating layer 478 selectively provided over the gate insulating layer 477. Thus, the gate insulating layer 478 may be selectively provided under the gate electrode layer, and end an end portion thereof may have a tapered shape. In FIG. 13C, end portions of either the gate insulating layer 478 or the gate electrode layer formed thereover have a tapered shape; however, they may be formed to have steps in a displaced manner.

As described above, the gate electrode layer may have various structures according to the structure and shape thereof. Therefore, a display device manufactured thereby has various structures. A structure and concentration distribution of an impurity region in a semiconductor layer changes according to the structure of the gate electrode layer in the case where the impurity region is formed using the gate electrode layer as a mask in a self-aligned manner. A thin film transistor having a desired function can be manufactured by designing in consideration of the aforementioned aspects.

This embodiment mode can be implemented in combination with any one of Embodiment Modes 1 to 3.

### EMBODIMENT MODE 5

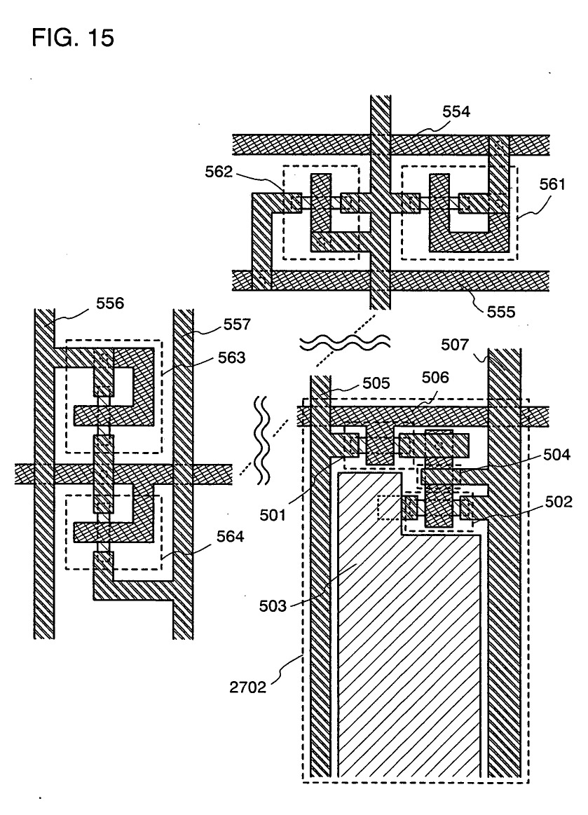

Hereinafter described with reference to FIG. 15 is a mode in which a protective diode is provided for a scan line side input terminal portion and a signal line side input terminal portion. In FIG. 15, a pixel 2702 is provided with TFTs 501 and 502, a capacitor 504, and a light emitting element 503. These TFTs have similar structures to Embodiment Mode 1.

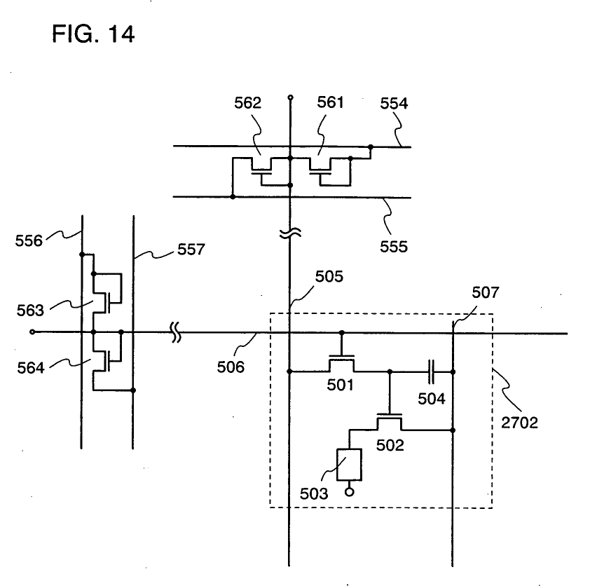

Protective diodes 561 and 562 are provided in the signal line side input terminal portion. These protective diodes are manufactured by similar steps to the TFTs 501 and 502, thereby a gate and one of a drain and a source are connected to operate as a diode. FIG. 14 shows an equivalent circuit diagram of a top view of FIG. 15.

The protective diode 561 includes a gate electrode layer, a semiconductor layer, and a wiring layer. The protective diode 562 has a similar structure. Common potential lines 554 and 555 connected to these protective diodes are formed of the same layer as the gate electrode layer. Accordingly, a contact hole is required to be formed in an insulating layer so as to be electrically connected to the wiring layer.

A contact hole in the insulating layer may be formed by forming a mask layer and applying etching thereto. In this case, by applying etching of atmospheric pressure discharge, local electric discharge can be performed, in which case a mask layer is not required to be formed over the entire surface of the substrate.

The signal wiring layer is formed of the same layer as a source and drain wiring layer 505. The signal wiring layer and the source or drain side are connected to each other.

An input terminal portion on the scan signal line side has a similar structure. A protective diode 563 includes a gate electrode layer, a semiconductor layer, and a wiring layer. A protective diode 564 has a similar structure. Common potentials 556 and 557 connected to these protective diodes are formed of the same layer as the source electrode layer and drain electrode layer. The protective diodes provided in the input stage can be formed at the same time. It is to be noted that the protective diode is not limited to be disposed at a position shown in this embodiment mode, but may be disposed between a driver circuit and a pixel.

### EMBODIMENT MODE 6

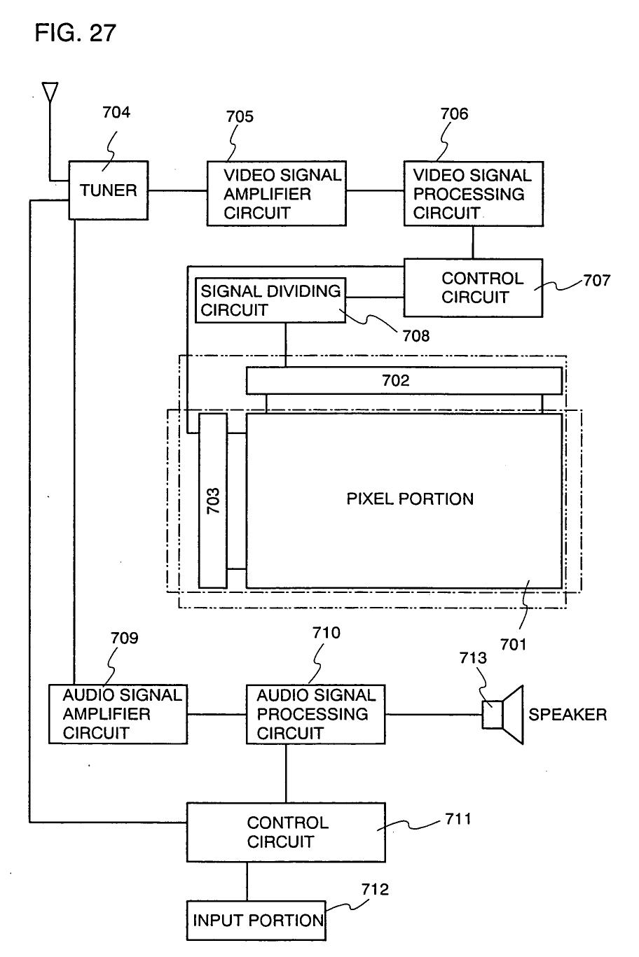

A television device can be completed with a display device formed according to the present invention. FIG. 27 is a block diagram showing a main structure of the television device (EL television device in this Embodiment Mode). A display panel can be formed in any manner as follows: as the structure shown in FIG. 16A, only a pixel portion 701 is formed, and a scan line driver circuit 703 and a signal line driver circuit 702 are mounted by a TAB method as shown in FIG. 17B; or as the structure shown in FIG. 16A, only a pixel portion 701 is formed, and a scan line driver circuit 703 and a signal line driver circuit 702 are mounted by a COG method as shown in FIG. 17A; a TFT is formed of a SAS, a pixel portion 701 and a scan line driver circuit 703 are formed to be integrated over a substrate, and a signal line driver circuit 702 is separately mounted as a driver IC as shown in FIG. 16B; a pixel portion 701, a signal line driver circuit 702, and a scan line driver circuit 703 are formed to be integrated over the substrate as shown in FIG. 16C; or the like.

Another structure of an external circuit includes a video signal amplifier circuit 705 which amplifies a video signal among signals received by a tuner; a video signal processing circuit 706 which converts the signal output therefrom into a chrominance signal corresponding to each color of red, green, and blue; a control circuit which converts the video signal into an input specification of a driver IC; and the like on the input side of the video signal. The control circuit 707 outputs the signal into the scan line side and the signal line side, respectively. In the case of digital driving, a signal dividing circuit 708 may be provided on the signal line side, so that an input digital signal is provided by dividing into m-pieces.

Among signals received from the tuner 704, an audio signal is transmitted to an audio signal amplifier circuit 709, and the output thereof is supplied for a speaker 713 through an audio signal processing circuit 710. The control circuit 711 receives control information on a receiving station (a receiving frequency) or sound volume from an input portion 712 and transmits the signal to the tuner 704 or the audio signal processing circuit 710.

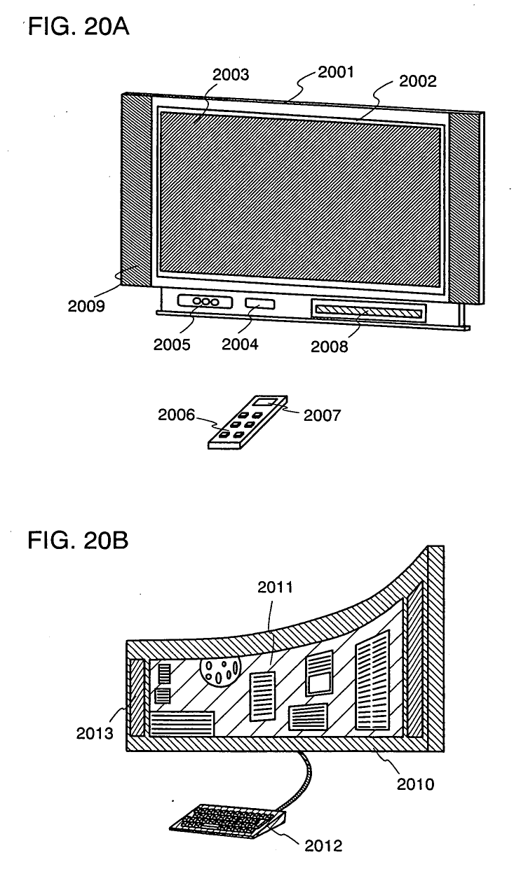

As shown in FIGS. 20A and 20B, a television device can be completed by incorporating a display module into a chassis. The display panel in which an FPC is attached as shown in FIG. 1 is generally called an EL display module. An EL television device can be completed when the EL display module as in FIG. 1 is used. A main screen 2003 is formed by using the display module, and a speaker unit 2009, operation switches, and the like are provided as other attached equipments. In such a manner, the television device can be completed according to the present invention.

In addition, reflected light of light entered from exterior may be shielded by using a wave plate and a polarizing plate. In the case of a top emission display device, an insulating layer which is to be a bank may be colored to be used as a black matrix. The bank can be formed by a droplet discharging method or the like, and a black resin pigment, a resin material such as polyimide, which is mixed with carbon black, or the like may be used, or a stacked structure thereof may also be used. Depending on a droplet discharging method, different materials may be discharged on the same region plural times to form the bank. Quarter or half wave plates may be used as wave plates and may be designed to be able to control light. As the structure, a TFT element substrate, a light emitting element, a sealing substrate (sealing material), wave plates (quarter or half wave plates), a polarizing plate are stacked in order, in which light emitted from the light emitting element is emitted outside from the polarizing plate side through the above components. The wave plate or polarizing plate may be provided on a side where light is emitted or may be provided on the both sides in the case of a dual emission type display device in which light is emitted from the both faces. In addition, an anti-reflective film may be provided on the outer side of the polarizing plate. Consequently, a higher definition and higher accurate image can be displayed.

As shown in FIG. 20A, a display panel 2002 using a display element is incorporated into a chassis 2001. By using a receiver 2005, in addition to reception of general TV broadcast, information communication can also be carried out in one direction (from a transmitter to a receiver) or in the both directions (between a transmitter and a receiver or between receivers) by connecting to a communication network by a fixed line or wirelessly through a modem 2004. The operation of the television device can be carried out by switches incorporated in the chassis or by a remote control device 2006, which is separated from the main body. A display portion 2007 that displays information to be output may also be provided in this remote control device.

In addition, in the television device, a structure for displaying a channel, sound volume, or the like may be additionally provided by forming a sub-screen 2008 as a second display panel in addition to the main screen 2003. In this structure, the main screen 2003 is formed of an EL display panel superior in a viewing angle, and the sub-screen may be formed of a liquid crystal display panel capable of displaying the sub-screen with low power consumption. In order to prioritize low power consumption, a structure in which the main screen 2003 is formed of a liquid crystal display panel, the sub-screen is formed of an EL display panel, and the sub-screen is able to flash on and off may also be applied. According to the present invention, a display device with high reliability can be manufactured using such a large substrate even when many TFIs and electronic parts are used.

FIG. 20B shows a television device having a large display portion of, for example, 20 to 80 inches, which includes a chassis 2010, a keyboard 2012 which is an operation portion, a display portion 2011, a speaker unit 2013, and the like. The invention is applied to manufacturing the display portion 2011. FIG. 20B shows a television device having a curved display portion since a bendable material is used for the display portion. Thus, a television device having a desired shape can be manufactured since the shape of the display portion can be freely designed.

According to the present invention, a display device can be manufactured through a simplified process and thus the manufacturing cost can be reduced. Hence, even a television device with a large screen display portion can be formed with low cost by applying the present invention. Accordingly, a high-performance and highly reliable television device can be manufactured with high yield.

Note that the present invention is not limited to the television device and is applicable to various usages especially to the display mediums having a large area such as an information display board at a station, an airport, or the like, or an advertisement display board on the street as well as a monitor of a personal computer.

### EMBODIMENT MODE 7

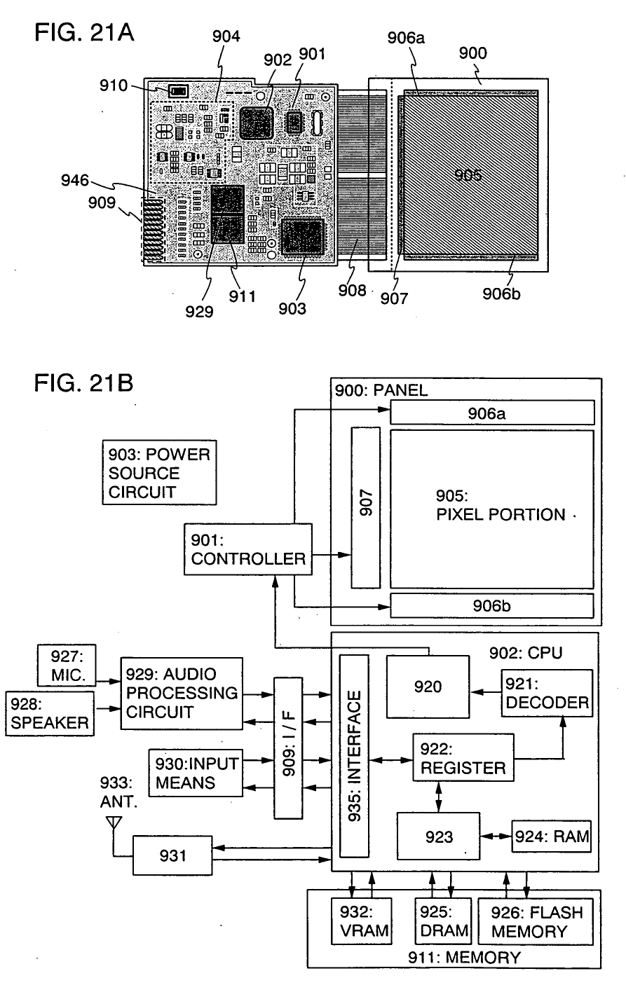

This embodiment mode is described with reference to FIGS. 21A and 21B. In this embodiment mode, description is made on an example of a module using a panel with a display device manufactured according to Embodiment Modes 1 to 6.

An information terminal module shown in FIG. 21A has a printed circuit board 946 over which a controller 901, a central processing unit (CPU) 902, a memory 911, a power source circuit 903, an audio processing circuit 929, a transmission/reception circuit 904, and other elements such as a resistor, a buffer, and a capacitor and mounted. Further, a panel 900 is connected to the printed circuit board 946 through a flexible printed circuit (FPC) 908.

The panel 900 includes a pixel portion 905 in which each pixel has a light emitting element, a first scan line side driver circuit 906a and a second scan line side driver circuit 906b which select a pixel in the pixel portion 905, and a signal line driver circuit 907 which supplies a video signal to the selected pixel.

Various signals are inputted and outputted through an interface (I/F) 909 provided over the printed circuit board 946. An antenna port 910 for transmitting and receiving signals with an antenna is provided over the printed circuit board 946.

It is to be noted that the printed circuit board 946 is connected to the panel 900 through the FPC 908 in this embodiment mode, however, the invention is not limited to this structure. The controller 901, the audio processing circuit 929, the memory 911, the CPU 902 or the power source circuit 903 may be directly mounted to the panel 900 by the COG (Chip On Glass) method. Further, various elements such as a capacitor and a buffer are provided over the printed circuit board 946, thereby it can be prevented that a noise occurs in the power source voltage and signals and the signal rise time becomes slow.

FIG. 21B is a block diagram of a module shown in FIG. 21A. This module 999 includes a VRAM 932, a DRAM 925, a flash memory 926 and the like as a memory 911. The VRAM 932 has data on the image to be displayed on a panel, the DRAM 925 has image data or audio data, and the flash memory has various programs.

The power source circuit 903 generates a power source voltage applied to the panel 900, the controller 901, the CPU 902, the audio processing circuit 929, the memory 911, and the transmission/reception circuit 931. There is a case where a current source is provided in the power source circuit 903 depending on the specifications of the panel.

The CPU 902 includes a control signal generating circuit 920, a decoder 921, a register 922, an arithmetic circuit 923, a RAM 924, an interface 935 for the CPU and the like. Various signals inputted to the CPU 902 through the interface 935 are held in the resister 922 and then inputted to the arithmetic circuit 923, the decoder 921 and the like. In the arithmetic circuit 923, an arithmetic operation is performed based on the inputted signal, and the address of various instructions is determined. Meanwhile, a signal inputted to the decoder 921 is decoded and inputted to the control signal generating circuit 920. The control signal generating circuit 920 generates a signal containing various instructions based on the inputted signal, and then transmits the signals to the address determined by the arithmetic circuit 923, specifically the memory 911, the transmission/reception circuit 931, the audio processing circuit 929, the controller 901 and the like.

Each of the memory 911, the transmission/reception circuit 929, and the controller 901 operates according to the received instruction. The operation thereof is briefly described.

A signal inputted from an input means 930 is transmitted to the CPU 902 which is mounted to the printed circuit board 946 through the interface 909. The control signal generating circuit 920 converts the image data stored in the VRAM 932 into a predetermined format based on the signal transmitted from the input means 930 such as a pointing device and a keyboard, and transmits the data to the controller 901.

The controller 901 processes the signals containing image data transmitted from the CPU 902 according to the specifications of the panel and then transmits the signals to the panel 900. Further, the controller 901 generates an Hsync signal, a Vsync signal, a clock signal CLK, an alternating current voltage (AC Cont), and a switching signal L/R based on the power source voltage inputted from the power source circuit 903 and the various signals inputted from the CPU 902, and supplies the signals to the panel 900.

The transmission/reception circuit 904 processes signals which are transmitted and received as electromagnetic waves by an antenna 933. In specific, the transmission/reception circuit 904 includes a high frequency circuit such as an isolator, a band pass filter, a VCO (Voltage Controlled Oscillator), an LPF (Low Pass Filter), a coupler, and a balun. A signal containing audio data among the signals transmitted and received by the transmission/reception circuit 904 is transmitted to the audio processing circuit 929 according to the instruction of the CPU 902.

The signal containing audio data transmitted according to the instruction of the CPU 902 is demodulated into an audio signal by the audio processing circuit 929 and transmitted to a speaker 928. An audio signal transmitted from a microphone 927 is modulated by the audio processing circuit 929 and transmitted to the transmission/reception circuit 904 according to the instruction of the CPU 902.

The controller 901, the CPU 902, the power source circuit 903, the audio processing circuit 929, and the memory 911 can be mounted as a package of this embodiment mode. This embodiment mode can be applied to any circuits but a high frequency circuit such as an isolator, a band pass filter, a VCO (Voltage Controlled Oscillator), an LPF (Low Pass Filter), a coupler, and a balun.

### EMBODIMENT MODE 8

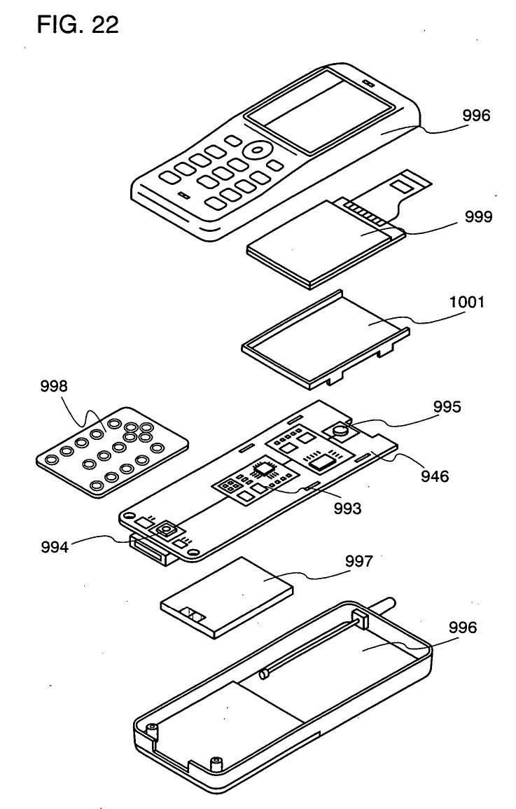

This embodiment mode is described with reference to FIGS. 21A to 22. FIG. 22 shows one mode of a wireless compact phone (cellular phone) including the module manufactured according to Embodiment Mode 8. The panel 900 which is detachable can be incorporated in a housing 1001 and easily integrated with the module 999. The shape and size of the housing 1001 can be appropriately changed in accordance with an electronic device.

The housing 1001 to which the panel 900 is fixed is mounted on the printed circuit board 946 and completed as a module. The printed circuit board 946 incorporates a controller, a CPU, a memory, a power source circuit, and other elements such as a resistor, a buffer, and a capacitor. Further, an audio processing circuit including a microphone 994 and a speaker 995, and a signal processing circuit 993 such as a transmission/reception circuit are provided. The panel 900 is connected to the printed circuit board 946 through the FPC 908.

Such module 999, an input means 998, and a buttery 997 are stored in a housing 996. A pixel portion of the panel 900 is disposed to be seen from an opening window formed in the housing 996.

A housing 996 shown in FIG. 22 shows an example of an external appearance of a phone. An electronic device according to this embodiment mode may change into various modes according to the function and application. An example of the modes is described in the following embodiment mode.

### EMBODIMENT MODE 9

Various display devices can be manufactured by applying the present invention. In other words, the invention can be applied to various electronic devices in which these display devices are incorporated into display areas.

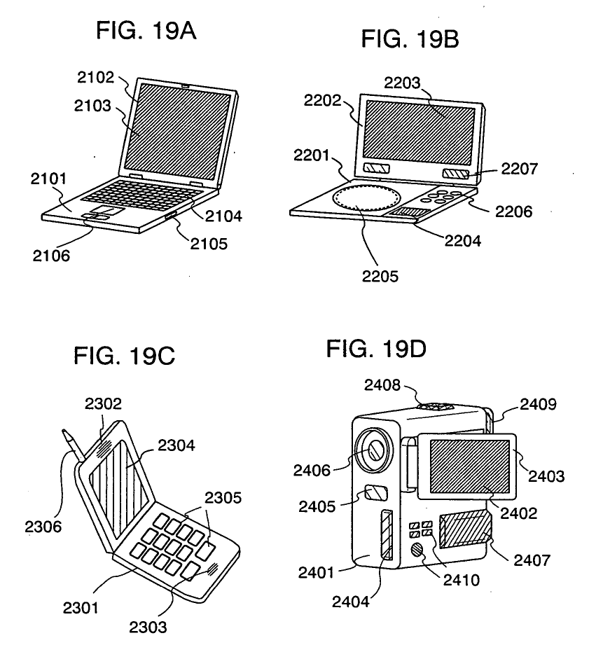

The electronic devices include a camera such as a video camera or a digital camera, a projector, a head mounted display (a goggle type display), a car navigation system, a car stereo, a personal computer, a game machine, a portable information terminal (a mobile computer, a cellular phone, an electronic book, or the like), an image reproducing device provided with a recording medium (specifically a device that is capable of playing a recording medium such as a Digital Versatile Disc (DVD) and that has a display device that can display the image) or the like. FIGS. 19A to 19D show the examples thereof.

FIG. 19A shows a computer, which includes a main body 2101, a chassis 2102, a display area 2103, a keyboard 2104, an external connection port 2105, a pointing mouse 2106 and the like. According to the invention, a computer by which an image with high reliability and high resolution can be displayed can be completed even if the computer is miniaturized and a pixel is minute.

FIG. 19B shows an image reproducing device provided with a recording medium (specifically a DVD reproducing device), which includes a main body 2201, a chassis 2202, a display area A 2203, a display area B 2204, a recording medium (such as a DVD) reading portion 2205, operation keys 2206, a speaker portion 2207 and the like. The display area A 2203 mainly displays image information and the display area B 2204 mainly displays character information. According to the invention, an image producing device by which an image with high reliability and high resolution can be displayed can be completed even when the image reproducing device is miniaturized and a pixel is minute.

FIG. 19C shows a cellular phone, which includes a main body 2301, an audio output portion 2302, an audio input portion 2303, a display area 2304, operation switches 2305, an antenna 2306, and the like. According to the invention, a cellular phone by which an image with high reliability and high resolution can be displayed can be completed even when the cellular phone is miniaturized and a pixel is minute.

FIG. 19D shows a video camera, which includes a main body 2401, a display area 2402, a chassis 2403, an external connection port 2404, a remote control receiving portion 2405, an image receiving portion 2406, a battery 2407, an audio input portion 2408, an eyepiece 2409, operation keys 2410, and the like. According to the invention, a video camera by which an image with high reliability and high resolution can be displayed can be completed even when the video camera is miniaturized and a pixel is minute. This embodiment mode can be freely combined with the above embodiment modes.

### EXAMPLE 1

In this embodiment, the result of measuring the characteristics of a film containing an aluminum alloy containing at least one or more selected from the group consisting of molybdenum, titanium, and carbon, which is used as an electrode layer in the present invention will be shown.

Chip-like molybdenum, titanium, or carbon is each prepared on an aluminum target and sputtered to form a film containing aluminum alloy containing molybdenum (Al(Mo)), a film containing an aluminum alloy containing titanium (Al(Ti)), and a film containing an aluminum alloy containing carbon (Al(C)). The deposition condition is as follows: the power at 1.5 to 2 kW, the pressure at 0.4 Pa, and the Ar gas flow rate at 50 sccm. The content of molybdenum in the Al(Mo) film, the content of titanium in the Al(Ti) film, and the content of carbon in the Al(C) film in samples are varied and the characteristics of each sample are evaluated.

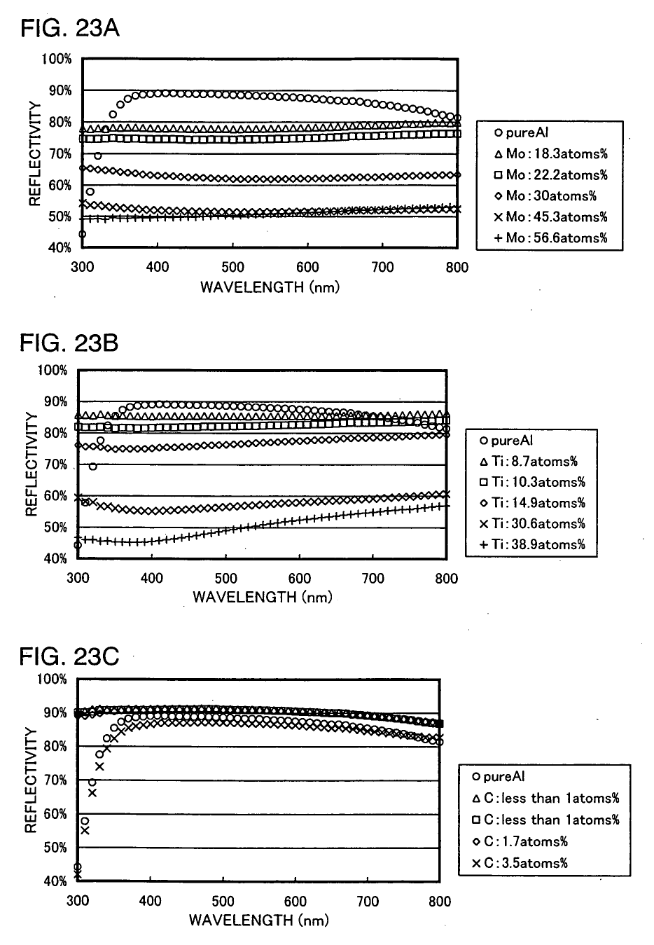

First, the reflectance of films containing an aluminum alloy containing at least one or more selected from the group consisting of molybdenum, titanium, and carbon is measured. Five kinds of Al(Mo) films in which the molybdenum contents are 18.3 atomic %, 22.2 atomic %, 30.0 atomic %, 45.3 atomic %, and 56.6 atomic %; five kinds of Al(Ti) films in which the contents of titanium are 8.7 atomic %, 10.3 atomic %, 14.9 atomic %, 30.6 atomic %, and 38.9 atomic %; four kinds of Al(C) films in which two of them have carbon contents of less than 1 atomic % and the others respectively have carbon contents of 1.7 atomic % and 3.5 atomic %; and a pure aluminum film (referred to as pure-Al as legends in FIG. 23A to 23C) are used as samples. Note that the samples are heated at 300° C. for one hour after the deposition in advance of the measurement, with real processes in mind. A heating step is commonly carried out after forming a reflective electrode in real processes. The reflectance of each sample of Al(Mo) to each wavelength is shown in FIG. 23A, the reflectance of each sample of Al(Ti) to each wavelength is shown in FIG. 23B, and the reflectance of each sample of Al(C) to each wavelength is shown in FIG. 23C.

In FIG. 23A, the circles indicate the pure aluminum film, the triangles indicate the measured value of the Al(Mo) film containing 18.3 atomic % of molybdenum, the squares indicate the measured value of the Al(Mo) film containing 22.2 atomic % of molybdenum, the rhombuses indicate the measured value of the Al(Mo) film containing 30.0 atomic % of molybdenum, the saltires indicate the measured value of the Al(Mo) film containing 45.3 atomic % of molybdenum, and the crosses indicate the measured value of the Al(Mo) film containing 56.6 atomic % of molybdenum. In the similar manner, in FIG. 23B, the circles indicate the pure aluminum film, the triangles indicate the measured value of the Al(Ti) film containing 8.7 atomic % of titanium, the squares indicate the measured value of the Al(Ti) film containing 10.3 atomic % of titanium, the rhombuses indicate the measured value of the Al(Ti) film containing 14.9 atomic % of titanium, the saltires indicate the measured value of the Al(Ti) film containing 30.6 atomic % of titanium, and the crosses indicate the measured value of the Al(Ti) film containing 38.9 atomic % of titanium. In FIG. 23C, the circles indicate the pure aluminum film, the triangles and the squares indicate the measured value of the Al(C) films containing less than 1 atomic % of carbon, the rhombuses indicate the measured value of the Al(C) film containing 1.7 atomic % of carbon, and the saltires indicate the measured value of the Al(C) film containing 3.5 atomic % of carbon. The film indicated by triangles contains less carbon than the film indicated by squares even though the content of carbon is the same less than 1 atomic %. The samples of which reflectance is measured each have a thickness of 200 nm.

As shown in FIGS. 23A, 23B, and 23C, the reflectance of the pure aluminum film reduces at a wavelength of less than about 450 nm; however, as to most of the films each containing an aluminum alloy containing at least one or more selected from the group consisting of molybdenum, titanium, and carbon, the reflectance in a wavelength in the near visible region is almost constant and there is no reduction in reflectance. Therefore, the films each containing an aluminum alloy containing at least one or more selected from the group consisting of molybdenum, titanium, and carbon can keep a certain reflectance in a visible region due to wavelength-independence of the reflectance, thereby efficiently reflecting light emitted from the light emitting element to serve as a reflective electrode. Further, the films hardly absorb light, so that heat is hardly collected therein. Thus, deterioration of the light emitting element due to heat can also be prevented, and the reliability of the display device can be improved. Accordingly, such a display device can be sufficiently utilized without a decline in function even when it is used under strong light, for example, the outdoors. When the content of molybdenum, titanium, or carbon in the film is increased, the reflectance is reduced. In consideration of the light reflectivity in the case where the film is used as a reflective electrode, it is preferable that the content of molybdenum is 22.2 atomic % or less in the Al(Mo) film, the content of titanium is 14.9 atomic % or less in the Al(Ti) film, and the content of carbon in the Al(C) film is 1.7 atomic % or less.

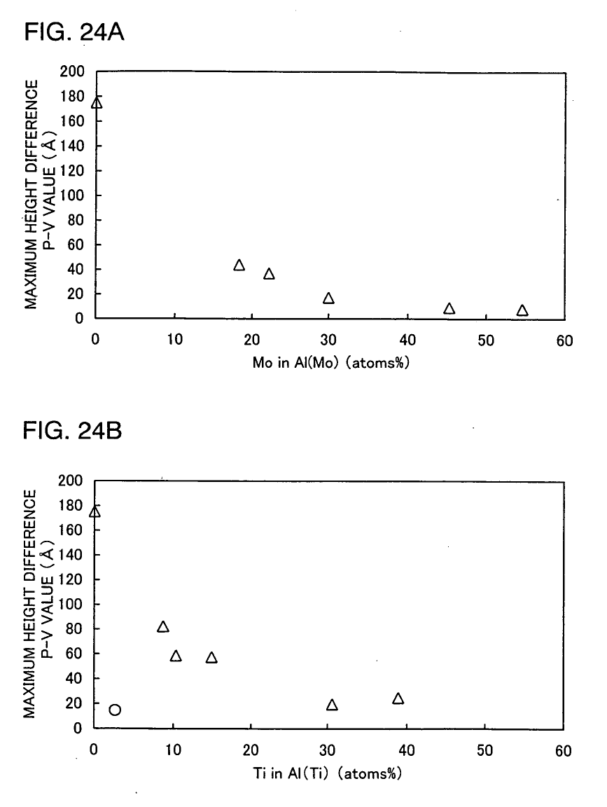

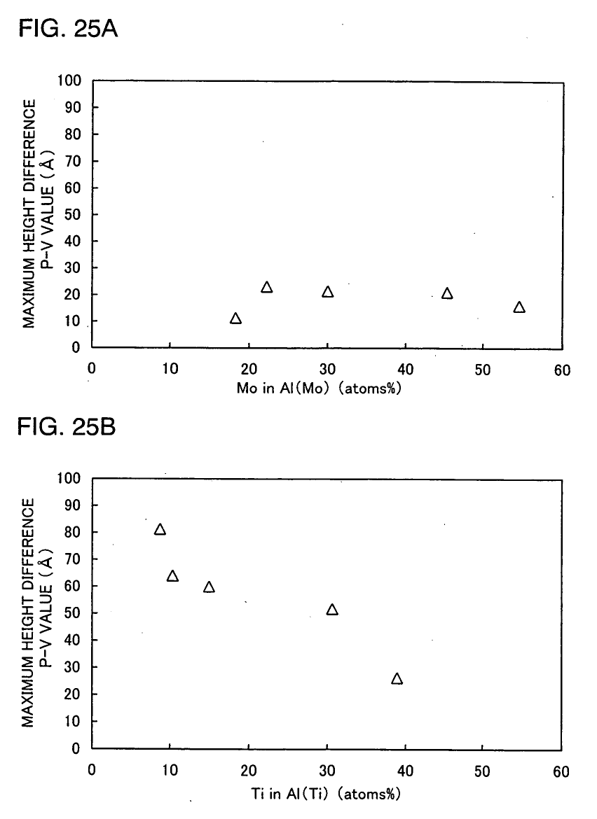

Next, the maximum height difference (Peak-Valley value (P-V value)) of the irregularities on the film surface of each sample is measured. The measurement is conducted using an atomic force microscope (AFM); the measurement range is 2 μm×2 μm. Change in the P-V value of the content of molybdenum in the Al(Mo) film is shown in FIG. 24A, and the change in the P-V value in accordance with the content of titanium in the Al(Ti) film is shown in FIG. 24B. In FIG. 24B, the circles indicate a film containing an aluminum alloy containing titanium and carbon, and the content of titanium in the film is 2.7 atomic % and the content of carbon therein is 1 atomic % or less. Further, FIGS. 24A and 24B show the results of evaluating the surface of the Al(Mo) film and the Al(Ti) film. An indium tin oxide film containing silicon oxide (an ITSO film) is formed on each of the Al(Mo) films and the Al(Ti) films. The P-V value of an upper layer of each of the surfaces of the ITSO films is measured; the results are shown in FIGS. 25A and 25B. The thickness of each sample of which the P-V value is measured is 35 nm.

In FIG. 24A, the measured P-V value of each sample is as follows: the pure aluminum film: 17.51 nm, the Al(Mo) film containing 18.3 atomic % of molybdenum: 4.421 nm, the Al(Mo) film containing 22.2 atomic % of molybdenum: 3.711 nm, the Al(Mo) film containing 30.0 atomic % of molybdenum: 1.738 nm, the Al(Mo) film containing 45.3 atomic % of molybdenum: 0.9358 nm, and the Al(Mo) film containing 56.6 atomic % of molybdenum: 0.8159 nm. In FIG. 24B, the measured P-V value of each sample is as follows: the pure aluminum film: 17.51 nm, the Al(Ti) film containing 8.7 atomic % of titanium: 8.239 nm, the Al(Ti) film containing 10.3 atomic % of titanium: 5.887 nm, the Al(Ti) film containing 14.9 atomic % of titanium: 5.75 nm, the Al(Ti) film containing 30.6 atomic % of titanium: 1.981 nm, the Al(Ti) film containing 38.9 atomic % of titanium: 2.493 nm, and the film containing an aluminum alloy containing titanium and carbon: 1.46 nm.

In FIG. 25A, the measured P-V value of the upper layer of each of the surfaces of the ITSO films is as follows: the Al(Mo) film containing 18.3 atomic % of molybdenum: 1.143 nm, the Al(Mo) film containing 22.2 atomic % of molybdenum: 2.32 nm, the Al(Mo) film containing 30.0 atomic % of molybdenum: 2.144 nm, the Al(Mo) film containing 45.3 atomic % of molybdenum: 2.109 nm, and the Al(Mo) film containing 56.6 atomic % of molybdenum: 1.603 nm. In FIG. 25B, the measured P-V value of the upper layer of each of the surfaces of the ITSO films is as follows: the Al(Ti) film containing 8.7 atomic % of titanium: 8.137 nm, the Al(Ti) film containing 10.3 atomic % of titanium: 6.407 nm, the Al(Ti) film containing 14.9 atomic % of titanium: 6.005 nm, the Al(Ti) film containing 30.6 atomic % of titanium: 5.178 nm, and the Al(Ti) film containing 38.9 atomic % of titanium: 2.635 nm.

The P-V Value of the surface of the pure aluminum film is twice or more than twice the P-V value of the surface of the Al(Mo) film, the Al(Ti) film, the film containing an aluminum alloy containing titanium and carbon, which reveals the bad planarity of the pure aluminum film. On the other hand, it is understood that the Al(Mo) film, the Al(Ti) film, the film containing an aluminum alloy containing titanium and carbon have good planarity on the surfaces since the P-V values thereof are low. Further, it is shown that the higher the content of molybdenum or titanium in the film containing an aluminum alloy containing at least one or more selected from the group consisting of molybdenum, titanium, and carbon is, the lower the P-V value tends to be. Further, the P-V value of the film containing an aluminum alloy containing titanium and carbon is as low as 1.46 nm even when the content of titanium is 2.7 atomic %. Thus, the effect of adding carbon for improving the surface planarity can be confirmed.

Further, a pure aluminum film and an Al(C) (the content of carbon in the film is less than 1 atomic %) film are formed. The crystallinity thereof is measured with an X-ray diffractometer (XRD) to evaluate the surface condition of the film baked at 300° C. The peak intensity in the diffraction peak of (111) of the Al(C) film is 684 CPS that is one seventh that of the pure aluminum film: 4341 CPS. Accordingly, the crystallinity of the pure aluminum is high since the crystallization is promoted. On the other hand, the crystallinity of the Al(C) film is low since the crystallization is suppressed. Consequently, it is considered that the planarity of the Al(C) film is high due to the low crystallinity.

From the above measurement results, it is confirmed that the surface planarity of a film can be improved and high reflectance can be obtained by adding one or more selected from molybdenum, titanium, and carbon to aluminum. When such a film is used for a reflective electrode of a display device, the extraction efficiency of light from the light emitting element is preferable, and a highly reliable display device in which a defect due to surface roughness of electrodes is reduced can be manufactured.

1. A display device comprising:
a thin film formed over a substrate, the thin film transistor including a semiconductor layer, a gate insulating layer, a gate electrode, and at least one of a source electrode and a drain electrode; and
a light emitting element electrically connected with at least one of the source electrode and the drain electrode,
wherein the light emitting element includes a first electrode and a second electrode with an electroluminescent layer interposed therebetween, and
wherein the first electrode contains aluminum, and at least one selected from the group consisting of molybdenum, titanium, and carbon.

2. A display device comprising:
a thin film transistor formed over a substrate, the thin film transistor including a semiconductor layer, a gate insulating layer, a gate electrode, and at least one of a source electrode and a drain electrode; and
a light emitting element electrically connected with the at least one of the source electrode and the drain electrode,
wherein the light emitting element includes a first electrode, a light-transmitting conductive film over the first electrode, an electroluminescent layer over the light-transmitting conductive film, and a second electrode over the electroluminescent layer, and
wherein the first electrode contains aluminum, and at least one selected from the group consisting of molybdenum, titanium, and carbon.

3. A display device comprising:
a thin film transistor formed over a substrate, the thin film transistor including a semiconductor layer, a gate insulating layer, a gate electrode, and at least one of a source electrode and a drain electrode;
an insulating layer of the thin film transistor;
an interlayer film provided over the insulating layer;
a light emitting element electrically connected with the at least one of the source electrode and the drain electrode,
wherein the light emitting element includes a first electrode and a second electrode with an electroluminescent layer interposed therebetween,
wherein the first electrode contains aluminum, and at least one selected from the group consisting of molybdenum, titanium, and carbon, and
wherein the layer film is provided only under the first electrode.

4. A display device comprising:
a thin film transistor formed over a substrate, the thin film transistor including a semiconductor layer, a gate insulating layer, a gate electrode, and at least one of a source electrode and a drain electrode;
an insulating layer over the thin film transistor;
an interlayer film provided over the insulating layer;
a light emitting element electrically connected with the at least one of the source electrode and the drain electrode,
wherein the light emitting element includes a first electrode, a light-transmitting conductive film over the first electrode, an electroluminescent layer over the light-transmitting conductive film, and a second electrode over the electroluminescent layer,
wherein the first electrode contains aluminum, and at least one selected from the group consisting of molybdenum, titanium, and carbon, and
wherein the interlayer film is provided only under the first electrode.

5. A display device according to claim 1, wherein a content of molybdenum or titanium in the first electrode is more than 7.0 atomic %.

6. A display device according to claim 5, wherein a content of molybdenum or titanium in the first electrode is 20 atomic % or less.

7. A display device according to claim 1, wherein a content of carbon in the first electrode is from 0.1 to 10 atomic %.

8. A display device according to claim 1, wherein the first electrode is reflective, and the second electrode is transparent.

9. A display device according to claim 1, wherein the electroluminescent layer has a layer containing an organic compound and an inorganic compound which is in contact with the first electrode.

10. A display device according to claim 1, wherein the first electrode is an alloy.

11. A display device according to claim 1, wherein the display device is incorporated in at least one selected from the group consisting of a computer, an image reproducing device, a cellular phone, a video camera, and a television.

12. A method for manufacturing a display device comprising:
forming a thin film transistor over a substrate, the thin film transistor including a semiconductor layer, a gate insulating layer, a gate electrode, and at least one of a source electrode and a drain electrode; and
forming a light emitting element electrically connected with the at least one of the source electrode and the drain electrode,
wherein the light emitting element includes a first electrode and a second electrode with an electroluminescent layer interposed therebetween, and
wherein the first electrode contains aluminum, and at least one selected from the group consisting of molybdenum, titanium, and carbon.

13. A method for manufacturing a display device comprising:
forming a thin film transistor over a substrate, the thin film transistor including a semiconductor layer, a gate insulating layer, a gate electrode, and at least one of a source electrode and a drain electrode; and
forming a light emitting element electrically connected with the at least one of the source electrode and the drain electrode,
wherein the light emitting element includes a first electrode, a light-transmitting conductive film over the first electrode, an electroluminescent layer over the light-transmitting conductive film, and a second electrode over the electroluminescent layer, and
wherein the first electrode contains aluminum, and at least one selected from the group consisting of molybdenum, titanium, and carbon.

14. A method for manufacturing a display device comprising:
forming a thin film transistor over a substrate, the thin film transistor including a semiconductor layer, a gate insulating layer, a gate electrode, and at least one of a source electrode and a drain electrode;
forming an insulating layer over the thin film transistor;
forming an interlayer film over the insulating layer;
forming an opening in the insulating layer and the interlayer film, which reaches to the at least one of the source electrode and the drain electrode;
forming a first conductive film containing aluminum, and at least one selected from the group consisting of molybdenum, titanium, and carbon over the opening and the interlayer film so as to contact the at least one of the source electrode and the drain electrode;
patterning the conductive film and the interlayer film to form a first electrode;
forming an electroluminescent layer over the first electrode; and
forming a second electrode over the electroluminescent layer.

15. A method for manufacturing a display device comprising:
forming a thin film transistor over a substrate, the thin film transistor including a semiconductor layer, a gate insulating layer, a gate electrode, and at least one of a source electrode and a drain electrode;
forming an insulating layer over the thin film transistor;
forming an interlayer film over the insulating layer;
forming an opening in the insulating layer and the interlayer film, which reaches to the at least one of the source electrode and the drain electrode;
forming a conductive film containing aluminum, and at least one selected from the group consisting of molybdenum, titanium, and carbon over the opening and the interlayer film so as to contact the at least one of the source electrode and the drain electrode;
forming a second conductive film over the first conductive film;
patterning the first conductive film, the second conductive film, and the interlayer film to form a first electrode;
forming an electroluminescent layer over the first electrode; and
forming a second electrode over the electroluminescent layer.

16. A method for manufacturing a display device according to claim 12, wherein the first electrode is formed to have more than 7.0 atomic % content of molybdenum or titanium.

17. A method for manufacturing a display device according to claim 16, wherein the first electrode is formed to have 20 atomic % or less content of molybdenum or titanium.

18. A method for manufacturing a display device according to claim 12, wherein the first electrode is formed to have 0.1 to 10 atomic % content of carbon.

19. A method for manufacturing a display device according to claim 12, wherein the first electrode is reflective, and the second electrode is transparent.

20. A method for manufacturing a display device according to claim 12, wherein the electroluminescent layer has a layer containing an organic compound and an inorganic compound which is in contact with the first electrode.

21. A method for manufacturing a display device according to claim 12, wherein the first electrode is an alloy.

22. A method for manufacturing a display device according to claim 12, wherein the display device is incorporated in at least one selected from the group consisting of a computer, an image reproducing device, a cellular phone, a video camera, and a television.

23. A display device according to claim 2, wherein a content of molybdenum or titanium in the first electrode is more than 7.0 atomic %.

24. A display device according to claim 23, wherein a content of molybdenum or titanium in the first electrode is 20 atomic % or less.

25. A display device according to claim 2, wherein a content of carbon in the first electrode is from 0.1 to 10 atomic %.

26. A display device according to claim 2, wherein the first electrode is reflective, and the second electrode is transparent.

27. A display device according to claim 2, wherein the electroluminescent layer has a layer containing an organic compound and an inorganic compound which is in contact with the first electrode.

28. A display device according to claim 2, wherein the first electrode is an alloy.

29. A display device according to claim 2, wherein the display device is incorporated in at least one selected from the group consisting of a computer, an image reproducing device, a cellular phone, a video camera, and a television.

30. A display device according to claim 3, wherein a content of molybdenum or titanium in the first electrode is more than 7.0 atomic %.

31. A display device according to claim 30, wherein a content of molybdenum or titanium in the first electrode is 20 atomic % or less.

32. A display device according to claim 3, wherein a content of carbon in the first electrode is from 0.1 to 10 atomic %.

33. A display device according to claim 3, wherein the first electrode is reflective, and the second electrode is transparent.

34. A display device according to claim 3, wherein the electroluminescent layer has a layer containing an organic compound and an inorganic compound which is in contact with the first electrode.

35. A display device according to claim 3, wherein the first electrode is an alloy.

36. A display device according to claim 3, wherein the display device is incorporated in at least one selected from the group consisting of a computer, an image reproducing device, a cellular phone, a video camera, and a television.

37. A display device according to claim 4, wherein a content of molybdenum or titanium in the first electrode is more than 7.0 atomic %.

38. A display device according to claim 37, wherein a content of molybdenum or titanium in the first electrode is 20 atomic % or less.

39. A display device according to claim 4, wherein a content of carbon in the first electrode is from 0.1 to 10 atomic %.

40. A display device according to claim 4, wherein the first electrode is reflective, and the second electrode is transparent.

41. A display device according to claim 4, wherein the electroluminescent layer has a layer containing an organic compound and an inorganic compound which is in contact with the first electrode.

42. A display device according to claim 4, wherein the first electrode is an alloy.

43. A display device according to claim 4, wherein the display device is incorporated in at least one selected from the group consisting of a computer, an image reproducing device, a cellular phone, a video camera, and a television.

44. A method for manufacturing a display device according to claim 13, wherein the first electrode is formed to have more than 7.0 atomic % content of molybdenum or titanium.

45. A method for manufacturing a display device according to claim 14, wherein the first electrode is formed to have more than 7.0 atomic % content of molybdenum or titanium.

46. A method for manufacturing a display device according to claim 15, wherein the first electrode is formed to have more than 7.0 atomic % content of molybdenum or titanium.

47. A method for manufacturing a display device according to claim 44, wherein the first electrode is formed to have 20 atomic % or less content of molybdenum or titanium.

48. A method for manufacturing a display device according to claim 45, wherein the first electrode is formed to have 20 atomic % or less content of molybdenum or titanium.

49. A method for manufacturing a display device according to claim 46, wherein the first electrode is formed to have 20 atomic % or less content of molybdenum or titanium.

50. A method for manufacturing a display device according to claim 13, wherein the first electrode is formed to have 0.1 to 10 atomic % content of carbon.

51. A method for manufacturing a display device according to claim 14, wherein the first electrode is formed to have 0.1 to 10 atomic % content of carbon.

52. A method for manufacturing a display device according to claim 15, wherein the first electrode is formed to have 0.1 to 10 atomic % content of carbon.

53. A method for manufacturing a display device according to claim 13, wherein the first electrode is reflective, and the second electrode is transparent.

54. A method for manufacturing a display device according to claim 14, wherein the first electrode is reflective, and the second electrode is transparent.

55. A method for manufacturing a display device according to claim 15, wherein the first electrode is reflective, and the second electrode is transparent.

56. A method for manufacturing a display device according to claim 13, wherein the electroluminescent layer has a layer containing an organic compound and an inorganic compound which is in contact with the first electrode.

57. A method for manufacturing a display device according to claim 14, wherein the electroluminescent layer has a layer containing an organic compound and an inorganic compound which is in contact with the first electrode.

58. A method for manufacturing a display device according to claim 15, wherein the electroluminescent layer has a layer containing an organic compound and an inorganic compound which is in contact with the first electrode.

59. A method for manufacturing a display device according to claim 13, wherein the first electrode is an alloy.

60. A method for manufacturing a display device according to claim 14, wherein the first electrode is an alloy.

61. A method for manufacturing a display device according to claim 15, wherein the first electrode is an alloy.

62. A method for manufacturing a display device according to claim 13, wherein the display device is incorporated in at least one selected from the group consisting of a computer, an image reproducing device, a cellular phone, a video camera, and a television.

63. A method for manufacturing a display device according to claim 14, wherein the display device is incorporated in at least one selected from the group consisting of a computer, an image reproducing device, a cellular phone, a video camera, and a television.

64. A method for manufacturing a display device according to claim 15, wherein the display device is incorporated in at least one selected from the group consisting of a computer, an image reproducing device, a cellular phone, a video camera, and a television.
